(19) United States
(12) Patent Application Publication
(10) Pub. No.: US 2015/0200259 A1
(43) Pub. Date: Jul. 16, 2015

(54) SEMICONDUCTOR DEVICE AND METHOD OF MANUFACTURING THE SAME

(71) Applicant: Samsung Electronics Co., Ltd., Suwon-si (KR)

(72) Inventors: Jong-Heun Lim, Hwaseong-si (KR); Myung-Jung Pyo, Hwaseong-si (KR); Kyung-Hyun Kim, Seoul (KR); Dong-Sik Kim, Suwon-si (KR); Hyo-Jung Kim, Seoul (KR)

(21) Appl. No.: 14/474,336

(22) Filed: Sep. 2, 2014

(30) Foreign Application Priority Data
Jan. 16, 2014 (KR) 10-2014-0005725

(51) Int. Cl. H01L 29/36; H01L 27/115; H01L 21/225; H01L 29/792

(52) U.S. Cl. CPC H01L 29/36; H01L 29/7926; H01L 27/11578; H01L 21/2253

(57) ABSTRACT

A method of manufacturing a vertical-cell-type semiconductor device may include stacking alternately first insulating layers and second insulating layers on a substrate, forming a channel hole through the first and second insulating layers, and forming dielectric layers. A channel layer and a gap fill pattern may be formed within the channel hole. The channel layer may cover a top surface of an uppermost first insulating layer. The top surface of the gap fill pattern is at the same level with the top surface of the channel layer. A first conductivity type impurities may be implanted into the channel layer to form a channel impurity region. A top surface of the gap fill pattern may be recessed. A contact pad on the recessed surface of the gap fill pattern may be formed. A ground selection gate electrode, cell gate electrodes, and string selection gate electrodes may be formed in interlayer spaces that be formed by removing the second insulating layers. String selection gate electrodes may formed in the channel impurity region.

### CROSS-REFERENCE TO RELATED APPLICATION

This application claims priority under 35 U.S.C. §119 to Korean Patent Application No. 10-2014-0005725 filed on Jan. 16, 2014, the disclosure of which is hereby incorporated by reference in its entirety.

### TECHNICAL FIELD

Exemplary embodiments in accordance with principles of inventive concepts provide a vertical-cell-type semiconductor device and a method of manufacturing the same.

### DISCUSSION OF RELATED ART

A vertical-cell-type semiconductor device and a method of manufacturing the same have been proposed, but ions implanted during an ion implantation process may have poor variation characteristics, which reduces a process margin.

### SUMMARY

Exemplary embodiments in accordance with principles of inventive concepts include a method of manufacturing a semiconductor device, comprising: stacking alternately first insulating layers and second insulating layers on a substrate, forming a channel hole through the first and second insulating layers, forming dielectric layers, a channel layer, and a gap fill pattern within the channel hole, wherein the channel layer covers a top surface of an uppermost first insulating layer, a top surface of the gap fill pattern is at the same level as a top surface of the channel layer, implanting a first conductivity type impurity into the channel layer to form a channel impurity region; recessing a top surface of the gap fill pattern, forming a contact pad on the recessed surface of the gap fill pattern, and forming ground selection gate electrode, cell gate electrodes, and string selection gate electrodes in interlayer spaces formed by removing the second insulating layers, wherein the string selection gate electrodes are formed corresponding to the channel impurity region.

Exemplary embodiments in accordance with principles of inventive concepts include a method wherein top surfaces of the dielectric layers are formed at a lower level than the top surface of the uppermost first insulating layer, the channel layer is formed along a side surface of an outermost dielectric layer, the top surfaces of the dielectric layers, and the upper side surface of the uppermost first insulating layer, and a portion of the channel layer vertically overlaps a portion of the gap fill pattern within the channel hole.

Exemplary embodiments in accordance with principles of inventive concepts include a method forming the channel impurity region comprises: implanting the first conductivity type impurities to vertically penetrate the gap fill pattern and then to stop in the channel layer.

Exemplary embodiments in accordance with principles of inventive concepts include a method comprising forming a hard mask between the uppermost first insulating layer and the channel layer.

Exemplary embodiments in accordance with principles of inventive concepts include a method wherein forming the dielectric layers comprises; forming a barrier layer in contact with an inner wall of the channel hole, forming a charge trap layer in contact with the barrier layer, and forming a tunneling layer in contact with the charge trap layer.

Exemplary embodiments in accordance with principles of inventive concepts include a method wherein the gap fill pattern comprises a lower gap fill pattern and an upper gap fill pattern disposed on the lower gap fill pattern, the upper gap fill pattern is fully overlapped with the lower gap fill pattern, a portion of the channel layer is vertically overlapped with a portion of the upper gap fill pattern with the channel hole, and a center of the top surface of the lower gap fill pattern is formed at a lower level than both ends of the top surface of the lower gap fill pattern.

Exemplary embodiments in accordance with principles of inventive concepts include a method wherein forming of the channel impurity region comprises: implanting the first conductivity type impurities to vertically penetrate the upper gap fill pattern and then to stop within the channel layer.

Exemplary embodiments in accordance with principles of inventive concepts include a method wherein the both ends of top surface of the lower gap fill pattern is formed at a higher level than a top end of the channel impurity region, and the center of the top surface of the lower gap fill pattern is formed at a lower level than a bottom end of the channel impurity region.

Exemplary embodiments in accordance with principles of inventive concepts include a method further comprising forming a drain region in the channel layer, wherein the drain region include a second conductivity type impurity and is formed on the channel impurity region.

Exemplary embodiments in accordance with principles of inventive concepts include a method wherein the drain region is formed to be in contact with a side surface of the contact pad, the contact pad includes carbon (C) and silicon (Si).

Exemplary embodiments in accordance with principles of inventive concepts include a method wherein forming of the channel impurity region comprises: implanting the first conductivity type impurities using an ion implantation energy of from about 90 to about 140 keV to implant ions at an ion projection range Rp, wherein the ion projection range Rp is the distance from the top surface of the gap fill pattern to a stop position of impurity ions in the channel layer between the first and second string selection gate electrodes.

Exemplary embodiments in accordance with principles of inventive concepts include a method wherein the string selection gate electrodes comprise a first string selection gate electrode and a second string selection gate electrode disposed over the first string selection gate electrode; the first conductivity type impurities are distributed as a broad Gaussian distribution within the channel impurity region; and wherein a highest concentration point of the first conductivity impurities is positioned in the channel impurity region corresponding to between the first and second string selection gate electrodes, a top end of the channel impurity region is formed at a level higher than the second string selection gate electrode, and a lower end of the channel impurity region is formed at a lower level than the first string selection gate electrode.

Exemplary embodiments in accordance with principles of inventive concepts include a method wherein the broad Gaussian distribution of the first conductivity type impurities is obtained by increasing the distance of the gap fill pattern through which the first conductivity type impurities passes, and the hard mask is formed thicker to increase the height of the gap fill pattern.

Exemplary embodiments in accordance with principles of inventive concepts include a method wherein the first conductivity type impurities is p-type impurities, and the p-type impurities include boron (B).

Exemplary embodiments in accordance with principles of inventive concepts include a method of manufacturing a semiconductor device, comprising: stacking alternately first insulating layers and second insulating layers on a substrate, forming a channel hole through the first and second insulating layers; forming dielectric layers, a channel layer, and gap fill pattern within the channel hole, wherein the channel layer covers a top surface of an uppermost first insulating layer, and a top surface of the gap fill pattern is at the same level with a top surface of the channel layer; implanting a first conductivity type impurities into the channel layer to form a channel impurity region; removing upper portions of the gap fill pattern, the channel layer, and dielectric layers, wherein after removing the upper portions of the gap fill pattern, the channel layer, and dielectric layers, a top surface of the dielectric layer is formed at a lower level than a top surface of the channel layer, and a top surface of the gap fill pattern is formed at a lower level than the top surface of the dielectric layer; forming a contact pad on the top surface of the gap fill pattern and a contacting ling on the top surfaces of the dielectric layers; wherein top surfaces of the contact pad, the channel layer, the contact ring, and the uppermost first insulating layer are formed at a same level; forming a drain region including a second type impurity on the channel impurity region; and forming a ground selection gate electrode, cell gate electrodes, and string selection gate electrodes in interlayer spaces that be formed by removing the second insulating layers; wherein the string selection gate electrodes are formed adjacent to the channel impurity region.

Exemplary embodiments in accordance with principles of inventive concepts include a device including insulating layers and gate electrodes alternately stacked on a substrate;

wherein the gate electrodes include a ground selection gate electrode, cell gate electrodes, and string selection gate electrodes; a channel hole disposed through the insulating layer and the gate electrodes; a gap fill pattern, a channel layer, and dielectric layers disposed within the channel hole; a channel impurity region formed in the channel layer corresponding to the string selection gate electrodes and containing a first conductivity type impurities; and a contact pad disposed on the gap fill pattern, wherein the contact pad includes a second conductivity type impurities and is free from the first conductivity type impurities.

Exemplary embodiments in accordance with principles of inventive concepts include a device including wherein the contact pad contains carbon (C) and silicon (Si).

Exemplary embodiments in accordance with principles of inventive concepts include a device wherein the first conductivity type impurity concentration of the channel impurity region is higher than that of the channel layer.

Exemplary embodiments in accordance with principles of inventive concepts include a device wherein the string selection gate electrodes include first and second string selection gate electrodes, and a highest impurity concentration point of the channel impurity region is positioned between the first and second string selection gate electrodes.

Exemplary embodiments in accordance with principles of inventive concepts include a device including wherein the second string selection gate electrode is disposed over the first string selection gate electrode, a top end of the channel impurity region is disposed at a higher level than the second string selection gate electrode, and a bottom end of the channel impurity region is disposed at a lower level than the first string selection gate electrode.

Exemplary embodiments in accordance with principles of inventive concepts include a device wherein the dielectric layers include a barrier layer is in contact with an inner wall of the channel, a charge trap layer is in contact with the barrier layer, and a tunneling layer is in contact with the charge trap layer.

Exemplary embodiments in accordance with principles of inventive concepts include a device including wherein a top surface of the gap fill pattern is at a higher level than the channel impurity region.

Exemplary embodiments in accordance with principles of inventive concepts include a device wherein the gap fill pattern comprises a lower gap fill pattern and an upper gap fill pattern disposed on the lower gap fill pattern, a center of the top surface of the lower gap fill pattern is a lower level than both ends of the top surface of the lower gap fill pattern.

Exemplary embodiments in accordance with principles of inventive concepts include a device including wherein the both ends of top surface of the lower gap fill pattern is at a higher level than a top end of the channel impurity region, and the center of the top surface of the lower gap fill pattern is at a lower level than a bottom end of the channel impurity region.

Exemplary embodiments in accordance with principles of inventive concepts include a device further comprising the channel impurity region disposed between the lower gap fill pattern and the dielectric layers.

Exemplary embodiments in accordance with principles of inventive concepts include a device further comprising a drain region disposed on the channel impurity region in the channel layer.

Exemplary embodiments in accordance with principles of inventive concepts include a device wherein the drain region is in contact with a side surface of the contact pad.

Exemplary embodiments in accordance with principles of inventive concepts include a device wherein the drain region contains n-type impurities and has an n-type impurity concentration lower than the contact pad.

Exemplary embodiments in accordance with principles of inventive concepts include a device wherein the first conductivity type impurities is p-type impurities, and the p-type impurities include boron (B).

Exemplary embodiments in accordance with principles of inventive concepts include a device including insulating layers and gate electrodes alternately stacked on a substrate; wherein the gate electrodes include a ground selection gate electrode, cell gate electrodes, and string selection gate electrodes; a channel hole disposed through the insulating layer and the gate electrodes; dielectric layers, channel layer, and a gap fill pattern disposed within the channel hole; wherein the channel layer is disposed between the gap fill pattern and the dielectric layers, top surfaces of the dielectric layers are at a lower level than a top surface of the channel layer, and a top surface of the gap fill pattern is at a lower level than the top surfaces of the dielectric layers, a contact pad disposed on the gap fill pattern and a contact ring disposed on the dielectric layers; and wherein top surfaces of the gap fill pattern, the channel layer, the contact ring, a uppermost insulating layer are at a same level, a drain region disposed on the channel impurity region.

Exemplary embodiments in accordance with principles of inventive concepts include a vertical-cell-type semiconductor device, including first and second vertically stacked transistor electrodes; and a channel impurity region vertically spanning the first and second transistor electrodes, with a point of highest impurity concentration at a level between the first and second transistor electrodes.

Exemplary embodiments in accordance with principles of inventive concepts include a device wherein the channel impurity region has a Gaussian distribution of impurity ions symmetrically distributed about the point of highest impurity concentration.

Exemplary embodiments in accordance with principles of inventive concepts include a device including structure to broaden the Gaussian distribution of impurity ions.

Exemplary embodiments in accordance with principles of inventive concepts include a device wherein the structure includes material to lengthen the implantation path of impurity ions to thereby broaden the Gaussian distribution.

Exemplary embodiments in accordance with principles of inventive concepts include a device include a portable electronic device including the vertical-cell-type semiconductor device.

Exemplary embodiments in accordance with principles of inventive concepts include a device include a portable electronic device, wherein the portable electronic device is a cellular telephone.

Exemplary embodiments in accordance with principles of inventive concepts include a portable electronic device, wherein the portable electronic device is a tablet computer.

Specific particulars of other embodiments are included in detailed descriptions and drawings.

### BRIEF DESCRIPTION OF THE DRAWINGS

The foregoing and other features and advantages of inventive concepts will be apparent from the more particular description of exemplary embodiments in accordance with principles of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1 is a cross-sectional view of a structure of a semiconductor device in accordance with an exemplary embodiment of inventive concepts;

FIG. 2 is an enlarged cross-sectional view of a region R1 of FIG. 1, in accordance with an exemplary embodiment of inventive concepts;

FIG. 3 is a cross-sectional view of a structure of a semiconductor device in accordance with an exemplary embodiment of inventive concepts;

FIG. 4 is an enlarged cross-sectional view of a region R2 of FIG. 3, in accordance with an exemplary embodiment of inventive concepts;

FIG. 5 is a cross-sectional view of a structure of a semiconductor device in accordance with an exemplary embodiment of inventive concepts;

FIG. 6 is an enlarged cross-sectional view of a region R3 of FIG. 5, in accordance with an exemplary embodiment of inventive concepts;

FIGS. 7 through 20 are diagrams illustrating a method of manufacturing a vertical-cell-type semiconductor device in accordance with an exemplary embodiment of inventive concepts;

FIGS. 21 through 34 are diagrams illustrating a method of manufacturing a vertical-cell-type semiconductor device in accordance with an exemplary embodiment of inventive concepts;

FIGS. 35 through 40 are diagrams illustrating a method of manufacturing a vertical-cell-type semiconductor device in accordance with an exemplary embodiment of inventive concepts;

FIGS. 41 through 44 are cross-sectional views illustrating process sequences of a method of manufacturing a vertical-cell-type semiconductor device in accordance with an exemplary embodiment of inventive concepts;

FIG. 45 is a diagram of a semiconductor module including at least one of semiconductor devices in accordance with exemplary various embodiments of inventive concepts;

FIG. 46 is a block diagram of an electronic system including at least one of semiconductor devices in accordance with exemplary embodiments of inventive concepts;

FIG. 47 is a block diagram of an electronic system including at least one of semiconductor devices in accordance with exemplary embodiments of inventive concepts; and

FIG. 48 is a diagram of a wireless mobile phone including at least one of semiconductor devices in accordance with exemplary embodiments of inventive concepts.

### DETAILED DESCRIPTION OF THE EMBODIMENTS

Various exemplary embodiments will be described more fully hereinafter with reference to the accompanying drawings, in which exemplary embodiments are shown. Exemplary embodiments may, however, be embodied in many different fours and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example, may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that tennis, such as those defined in commonly used dictionaries, should be interpreted as having a meaning that is consistent with their meaning in the context of the relevant art and will not be interpreted in an idealized or overly formal sense unless expressly so defined herein.

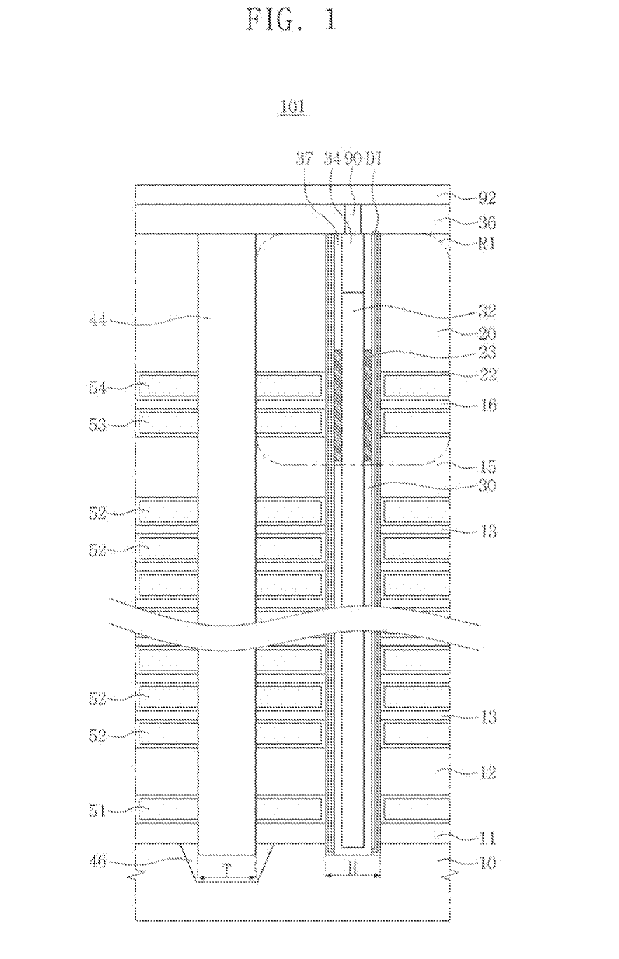

FIG. 1 is a cross-sectional view of a structure of a first exemplary embodiment of semiconductor device 101 in accordance with principles of inventive concepts. Semiconductor device 101 may include a substrate 10, insulating layers 11, 12, 13, 15, 16, and 20 disposed on the substrate 10, gate electrodes 51, 52, and 53 disposed between the insulating layers 11, 12, 13, 15, 16, 20, and 36.

The insulating layers 11, 12, 13, 15, 16, 20, and 36 may include a plurality of insulating layers 11, 12, 13, 15, and 16, a capping layer 20, and an interlayer insulating layer 36. The insulating layers 11, 12, 13, 15, 16, 20, and 36 may have different thicknesses. The capping layer 20 may be thicker than the other layers, for example.

The gate electrodes 51, 52, 53, and 54 may include the string selection gate electrodes 53 and 54, the cell gate electrode 52, and the ground selection gate electrode 51. The string selection gate electrodes 53 and 54 may be formed over the cell gate electrode 52. The cell gate electrodes 52 may be formed over the ground selection gate electrode 51.

The string selection gate electrodes 53 and 54 may include a first string selection gate electrode and a second string selection gate electrode. The cell gate electrodes 52 may be formed in two, four, eight, or sixteen layers, for example. The ground selection gate electrode 51 may be formed in one layer. In other exemplary embodiments, a string selection gate electrode may be formed in one layer, and the ground selection gate electrode 54 may be formed in two layers.

The insulating layers 11, 12, 13, 15, 16, and 20 and the gate electrodes 51, 52, 53, and 54 may be alternately stacked. The insulating layers 11, 12, 13, 15, 16, and 20 may include a first lower insulating layer 11 formed between the substrate 10 and the ground selection gate electrode 51, a second insulating layer 12 formed between the ground selection gate electrode 51 and the cell gate electrode 52, a third insulating layer 13 formed between the cell gate electrodes 52, a fourth insulating layer 15 formed between the cell gate electrodes 52 and the first string selection gate electrode 53, a fifth insulating layer 16 formed between the string selection gate electrodes 53 and 54, and the capping layer 20 formed between the second string selection gate electrode 54 and an interlayer insulating layer 36.

For example, the substrate 10 may include a rigid printed circuit board (PCB), a flexible PCB, or a rigid-flexible PCB. The substrate 10 may include a memory cell array region in which memory cells are formed, and a peripheral circuit region in which peripheral circuits configured to operate the memory cells are formed. The substrate 10 may include a semiconductor material doped with p-type impurities. For example, the p-type impurities may include boron (B), gallium (Ga), or indium (In). The semiconductor material may include polycrystalline silicon (poly-Si).

The insulating layers 11, 12, 13, 15, 16, and 20 may include silicon oxide (SiOₓ), and the gate electrodes 51, 52, 53, and 54 may include a conductive material, such as tungsten (W), copper (Cu), aluminum (Al), titanium (Ti), titanium nitride (TiN), tantalum (Ta), or doped silicon (n-type Si or p-type Si). The first semiconductor device 101 in accordance with principles of inventive concepts may further include a channel hole H, dielectric layers DI, blocking layers 22, a channel layer 30, a gap fill pattern 32, a channel impurity region 23, contact pad 34, and drain region 37.

The channel hole H may penetrate the insulating layers 11, 12, 13, 15, 16, and 20, the gate electrodes 51, 52, 53, and 53. The channel hole H may have a pillar shape, such as a cylindrical shape or a square pillar shape. The channel holes H may be formed in the semiconductor device 101 apart from one another. The dielectric layers DI may be formed along an inner side wall on the channel hole H. The blocking layers 22 may be disposed between the gate electrodes, the insulating layer 11, 12, 13, 15, 16, and 20, and dielectric layers. The dielectric layers DI and the blocking layers 22 may be referred to as a gate dielectric layers GD herein. The channel layer 30 may be in contact with the dielectric layers DI and may include p-type impurities. The channel impurities region 23 may be formed in the channel layer 30 and may include p-type impurities. The channel impurity region 23 may have a higher p-type impurities concentration than that of the channel layer 30. The gap fill pattern 32 may be in contact with the channel layer 30 and may be filled in the channel hole H. The contact pad 34 may be formed on the gap fill pattern 32. The contact pad 34 may include, for example, single crystalline silicon or poly-Si. The contact pad 34 may include n-type impurities and may be free from p-type impurities. The drain region may be formed in the channel layer and may include n-type impurities. The drain region 37 is disposed on the channel impurity region 23. The channel impurity region 23 may be formed adjacent to the string selection gate electrodes 53 and 54.

For example, the p-type impurities may contain boron (B), indium (In), or gallium (Ga). The n-type impurities may contain phosphorus (P) or arsenic (As). The contact pad 34 may contain carbon (C). The contact pad 34 may be doped with carbon (C). The interstitial site in the silicon grating may be a space between silicon atoms and may have a smaller size than the silicon atoms. When smaller atoms than the silicon atoms are implanted into the silicon grating, the atoms may tend to diffuse along the interstitial site. The carbon (C) may be fixed to an interstitial site in a silicon grating of poly-Si in the semiconductor device 101 and may prevent diffusion of p-type impurities (e.g., boron (B)) present on the channel layer 30.

The first semiconductor device 101 in accordance with principles of inventive concepts may further include a trench T, a device isolation layer 44, a interlayer insulating layer 36, contact plug 90, and a conductive line 92.

The trench T is spaced apart from the through-hole H and vertically penetrates the insulating layers 11, 12, 13, 15, 16, and 20 and the gate electrodes 51, 52, 53, and 54. The device isolation layer 44 may be filled in the trench T. A bottom of the trench T may correspond to the recessed surface of the substrate 10. A common source region 46 may be formed in the recessed surface of the substrate 10. The common source region 46 may form a p-n junction with the substrate 10. The common source region 46 may be a common source line CSL of the first semiconductor device 101. The common source region 46 may be electrically connected to the ground selection gate electrode GS. The common source region 46 may be doped with n-type impurities. The ground selection gate electrode 51 may be electrically connected to the common source region 46.

An interlayer insulating layer 36 may be formed on the capping layer 20. The contact plug 90 may be formed on the contact pad 34. A conductive line 92 may be in contact with the contact plug 90 and may be formed on the interlayer insulating layer 36.

The ground selection gate electrode 51 and the gate dielectric layer GD and the channel layer 30, which are electrically connected to the ground selection gate electrode 51, may constitute a ground selection transistor (GST). The cell gate electrodes 52 and the gate dielectric layer GD and the channel layer 30, which are electrically connected to the cell gate electrodes 52, may constitute a cell transistor (CT). The string selection gate electrodes 53 and 54 and the gate dielectric layer GD and the channel layer 30, which are electrically connected to the string selection gate electrodes 53 and 54, may constitute a string selection transistor (SST).

The CT may include a data storage element. The GST, the CT, and the string selection transistor may constitute one cell string and may be connected in series. The isolation layer 44 may be formed between the cell strings and may have a line shape. The cell strings may be symmetrically formed with respect to the isolation layer 44. The cell string may be electrically connected to a conductive line 92 through a contact pad 34 and a contact plug 90. The contact plug 90 may be a bit plug, and the conductive line 92 may be a bit line. A plurality of cell strings may be connected in parallel to one bit line.

A fringe field may be formed due to voltages applied to the string selection gate electrodes 53 and 52, the cell gate electrodes 52, and the ground selection gate electrode 51. The voltage applied to the string selection gate electrodes 53 and 52 may be a voltage used to select a cell string including the string selection gate electrodes 53 and 52.

Inversion regions may be formed in the channel layer 30 due to the fringe field. Inversion regions formed corresponding to the respective gate electrodes 51, 52, 53, and 54 may overlap one another. A current path may be formed from the bit line 80 to a common source line CSL through the overlapping inversion regions. The inversion regions may be conductive channel layers of metal oxide semiconductor field effect transistors (MOSFETs).

A threshold voltage may be the minimum voltage required to form an inversion region in the channel layer 30, for example.

When a voltage applied to the gate electrodes 51, 52, 53, and 54 exceeds the threshold voltage, electrons (negative charges) may be accumulated in a portion of the channel layer 30 close to the gate electrodes 51, 52, 53, and 54. The electrons may move toward the conductive line 92 (bit line) according to a voltage applied to the common source line CSL. For example, assuming that a voltage of about 0.5 V is applied between the bit line 80 and the common source line 46, the threshold voltage may be a gate voltage applied to the gate electrodes 51, 52, 53, and 54 when a current of about 1 μA flows per 1 μm-width of the bit line 80, from the bit line 80 toward the common source region 46. Since the channel layer 30 originally remains doped with p-type impurities, a region in which electrons carrying negative electric charges are generated may be referred to as an inversion region.

A threshold voltage Vt that is applied to the string selection gate electrodes 54, 54 for the semiconductor device 101 according to the embodiments of inventive concepts may range from about 1.5 V to 2.5 V. If the threshold voltage Vt were, for example, less than about 1.5 V, selecting a cell string connected to each string selection line SSL may not be error-free. At the higher end of the range, if the threshold voltage Vt were, for example, greater than 2.5V, the gate voltage required to drive a string selection transistor may increase, thereby increasing power consumption. For these reasons, at least, the threshold voltage Vt in accordance with principles of inventive concepts may be kept within a range of from about 1.5V to about 2.5V.

A method of controlling the threshold voltage that is applied to the string selection gate electrodes 54, 54 may include applying a voltage between the common source region 46 and the channel layer 30. Another method of controlling the threshold voltage may include implanting impurities in the channel layer 30 corresponding to the string selection gate electrodes 53, 54. The method for implanting the impurities may include performing an ion implantation process in which an ion projection range Rp relative to power may be precisely controlled. An ion implantation process in accordance with principles of inventive concepts may be used to control a threshold voltage of a transistor in the first semiconductor device 101 in accordance with principles of inventive concepts.

As previously indicated, the threshold voltage Vt is, in exemplary embodiments, the minimum voltage required to form an inversion region in a channel layer (for example, channel layer 30). If the threshold voltage were too low, the semiconductor device may not operate properly within the context of a larger circuit. That is, it may not be able to successfully activate a string selection line, for example. If the threshold voltage were too high, the device and circuits associated with it may consume more power than desirable. By precisely controlling the value of the threshold voltage, a semiconductor device in accordance with principles of inventive concepts may operate reliably without consuming an inordinate amount of power.

In exemplary embodiments in accordance with principles of inventive concepts the threshold voltage Vt may be controlled by ion implantation. The threshold voltage Vt may correlate to the ion projection range Rp which, in turn, may vary according to the energy with which ions are implanted; the injection energy. An increase in the injection energy, and a corresponding increase in the ion projection range Rp, may yield an increase in the region in which ions are implanted. The range of an implanted region may be expressed as a variation ΔRp in the ion projection range. In accordance with principles of inventive concepts, the variation in the ion projection range ΔRp may be increased without increasing the implantation dosage in order to reduce differences in threshold voltages, for example, between string selection transistors.

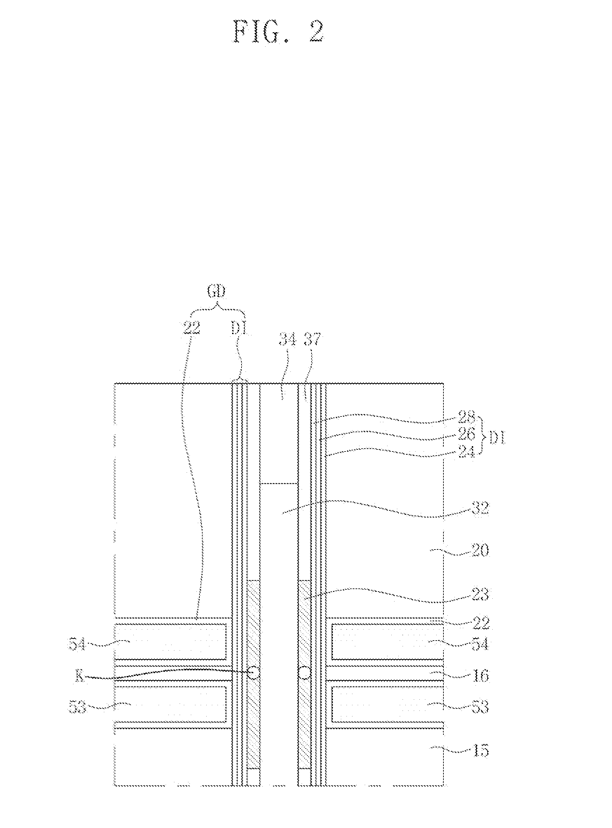

FIG. 2 is an enlarged view of a region R1 of the first semiconductor device in accordance with exemplary embodiments of inventive concepts. Dielectric layer DI may include a tunneling layer 28, a charge trap layer 26, and a barrier layer 24. One side surface of the tunneling layer 28 may be in contact with one side surface of the channel layer 30. One side surface of the charge trap layer 26 may be in contact with other side surface of the tunneling layer 28. One side surface of the barrier layer 24 may be in contact with other side surface of the charge trap layer 26. Another side surface of the barrier layer, also referred to herein as “other side surface,” may be in contact with the blocking layer 22.

The charge trap layer 116 may serve as an information storage layer that traps and holds electrons injected through the tunneling layer 118. The electrons trapped within the charge trap layer 116 may be removed from the charge trap layer 116.

The tunneling layer 28 may include silicon oxide (SiO_{X}). The charge trap layer 26 may include silicon nitride (SiNₓ). The barrier layer 24 may include silicon oxide (SiO_{X}). The blocking layer 22 may include a high-k dielectric material or a material having a large work function such as hafnium oxide (HfO₂) or aluminum oxide (Al₂O₃).

A side surface of the channel layer 30 that is not in contact with the tunneling layer 24 may be in contact with the gap fill pattern 32. A top surface of the gap fill pattern 32 may be formed at a higher level than a top end of the channel impurity region 23. A bottom surface of the contact pad 34 may be formed at a higher level than a top end of the channel impurity region 23 to prevent diffusion of the n-type impurities of the contact pad 34.

A drain region 37 may be formed on a side surface of the contact pad 34. The drain region 37 may be the resultant structure generated by diffusing n-type impurities from the contact pad 34 due to an annealing process. The contact pad 34 may be an n-type impurity implantation region. The drain region 37 may be an n-type impurity diffusion region. The p-type impurities implanted in the channel impurity region may be limited

A carbon-doped contact pad 34 may prevent which the p-type impurities of the channel impurity region is diffused to an outside. That is, ensuring the interstitial site may be limited, thereby preventing diffusion of boron ions from the channel layer 30 to the contact pad 34. The contact pad 34 may be free from p-type impurities.

The p-type impurities may be distributed as a Gaussian distribution in the channel impurity layer 23 in a vertical direction. The highest concentration point K of the p-type impurities may be formed in the channel impurity region corresponding to between the first string selection gate electrode 53 and the second string selection gate electrode 54. The implanting depth of the impurity ions at the highest concentration point K of the p-type impurities may be referred to as the ion projection range Rp. As previously indicated, in accordance with principles of inventive concepts, the threshold voltage of the first and second string selection transistors SST1 and SST2 may be controlled depending on the concentration of the impurity within the channel impurity region 23. The highest concentration point K of the channel impurity region may be formed in a middle region between the first and second string selection gate electrodes 53 and 54 and may reduce any differences in threshold voltages between the first and second string selection transistors SST1 and SST2. As a result, in accordance with principles of inventive concepts, first and second string selection transistors SST1 and SST2 may have substantially the same threshold voltage.

P-type impurities may be symmetrically doped from a region corresponding to the first string gate electrode 53 of the first string selection transistor SST1 to a region corresponding to the second string gate electrode 54 of the second string selection transistor SST2. The top end of the channel impurity region 23 may be formed at a higher level than a top surface of the second string selection gate electrode 54. A bottom end of the channel impurity region 23 may be formed at a lower level than a bottom surface of the first string selection gate electrode 53.

If the highest concentration point of the channel impurity region 23 were at a higher level than the point K in the channel layer 30, the threshold voltage of the second string selection transistor SST2 may be elevated. For example, if the threshold voltage of the second string selection transistor SST2 were higher than about 2.5V, the second string selection transistor SST2 may be degraded.

If the highest concentration point of the channel impurity region 23 were at a lower level than the point K in the channel layer 30, the threshold voltage of the first string selection transistor SST1 may be elevated. For example, if the threshold voltage of the first string selection transistor SST1 were higher than about 2.5V, the first string selection transistor SST1 may be degraded.

In accordance with principles of inventive concepts, with the highest concentration point K of channel impurities positioned at the same distance from the first and second string selection gate electrodes 53 and 54 in the channel layer 30 and the Gaussian distribution of the p-type impurity in the channel impurity region 32 broad, any differences in threshold voltages between the first and second string selection transistors SST1 and SST2 may be minimized.

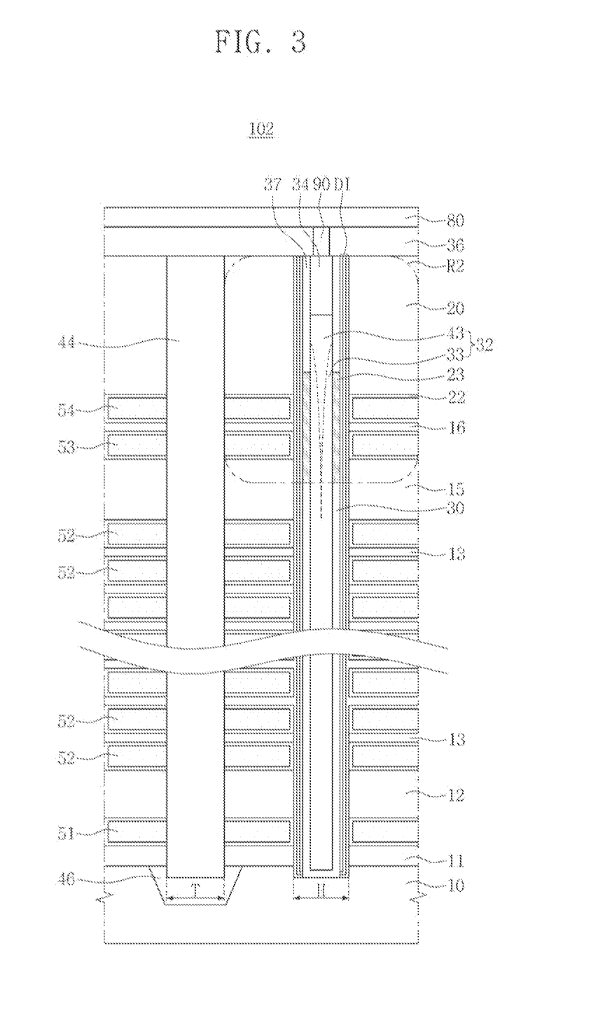

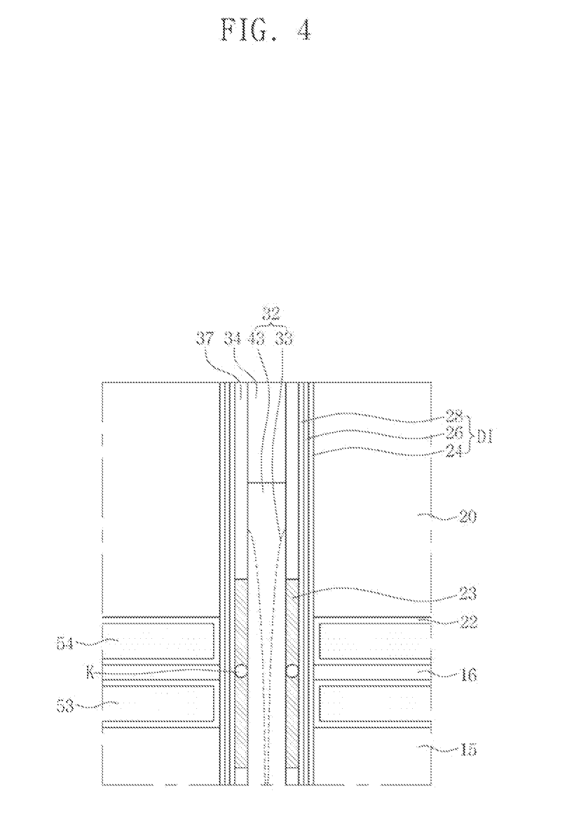

FIG. 3 is a cross-sectional view of a structure of a second exemplary embodiment of a semiconductor device in accordance with principles of inventive concepts. FIG. 4 is an enlarged view of a region R2 of the second exemplary embodiment of a semiconductor device in accordance with principles of inventive concepts.

Referring to FIG. 3, semiconductor device 102 in accordance with principles of inventive concepts may include string selection gate electrodes 53 and 54, a blocking layers 22, dielectric layers DI, channel layers 30, a channel impurity layer 23, a gap fill pattern 32, a contact pad 34, a contact plug 90, and a conductive line 92.

The gap fill pattern 32 may include a lower gap fill pattern 33 and an upper gap fill pattern 43. The upper gap fill pattern 43 may be formed at a higher level than the lower gap fill pattern 33. The upper gap fill pattern 43 may be denser than the lower gap fill pattern 33. As mentioned above, when the gap fill pattern 32 has a double structure, a space under the contact pad 34 may be densely filled to leave no space.

Referring to FIG. 4, the lower gap fill pattern 33 may cover a side surface of the channel impurity region 23. Because the upper gap fill pattern 43 is formed on the lower gap fill pattern 33 and pushes the lower gap fill pattern 33, the lower gap fill pattern 33 may also be dense. For example, the lower gap fill pattern 33 and the upper gap fill pattern 43 may include silicon oxide (SiO_{X}).

A bottom surface of the upper gap fill pattern 43 may be fully overlapped with a top surface of the lower gap fill pattern 33. A center of the top surface of the lower gap fill pattern 33 may be formed at a lower level than both ends of the top surface of the lower gap fill pattern 33.

Both ends of the top surface of the lower gap fill pattern 33 may be formed at a higher level than a top end of the channel impurity region 23. A center of the top surface of the lower gap fill pattern 33 may be formed at a lower level than a bottom end of the channel impurity region 23.

In accordance with principles of inventive concepts, with the highest concentration point K of channel impurities positioned at the same distance from the first and second string selection gate electrodes 53 and 54 in the channel layer 30 and the Gaussian distribution of the p-type impurity in the channel impurity, region 32 broad, any differences in threshold voltages between the first and second string selection transistors SST1 and SST2 may be minimized.

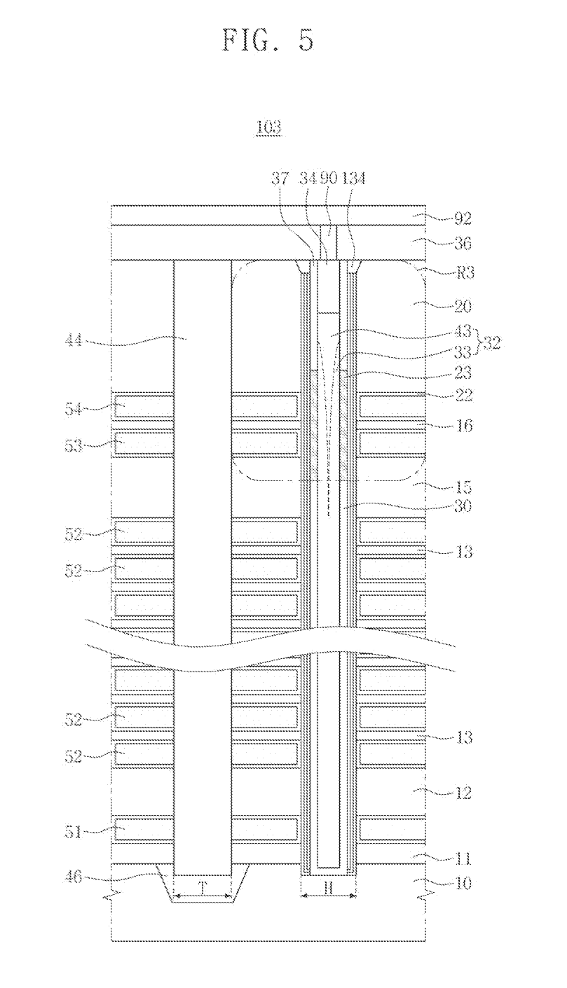

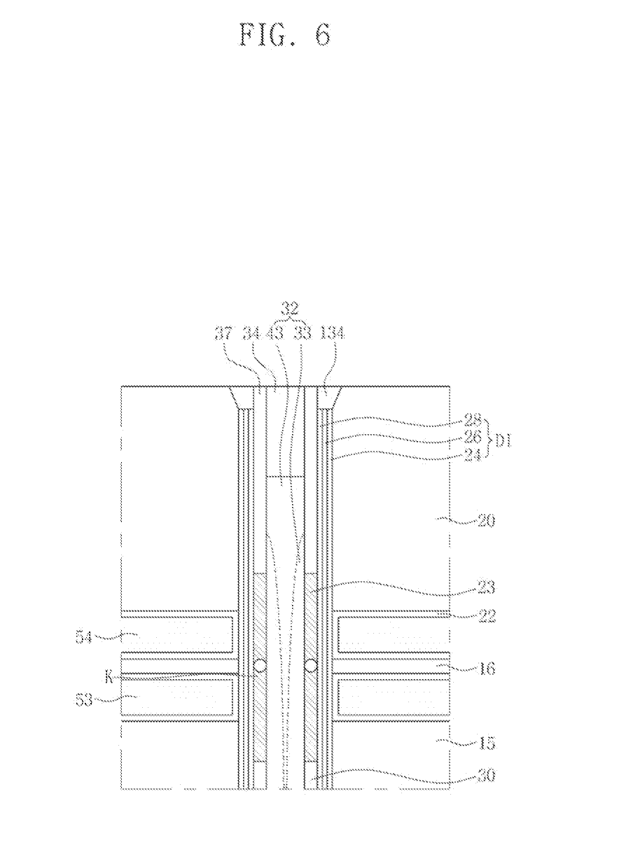

FIG. 5 is a cross-sectional view of a structure of a third exemplary embodiment of a semiconductor device in accordance with principles of inventive concepts. FIG. 6 is an enlarged view of a region R3 of the third exemplary embodiment of a semiconductor device in accordance with principles of inventive concepts.

Referring to FIGS. 5 and 6, the third semiconductor device 103 in accordance with principles of inventive concepts may include string selection gate electrodes 53 and 54, a blocking layers 22, dielectric layers DI, channel layers 30, a channel impurity layer 23, a gap fill pattern 32, contact pad 34, a contact ring 134, a contact plug 90, and conductive line 92.

The gap fill pattern 32 may include the upper gap fill pattern 43 and the lower gap fill pattern 33. The dielectric layer DI may be etched back to a lower level than the top surface of the channel layer 32 and the capping layer 20. The contact ring 134 may be formed in a region in which the dielectric layer DI is etched back and recessed. Therefore, an upper portion of the channel layer 30 may be disposed between the contact pad 34 and the contact ring 134.

The upper portion of the channel layer 30 may be a drain region 37. The contact pad 34, the contact ring 134, and the drain region 37 may contain n-type impurities. For example, the n-type impurities may include phosphorus (P) or arsenic (As). The contact pad 34, the contact ring 134, and the drain region 37 may be electrically connected to each other.

In accordance with principles of inventive concepts, with the highest concentration point K of channel impurities positioned at the same distance from the first and second string selection gate electrodes 53 and 54 in the channel layer 30 and the Gaussian distribution of the p-type impurity in the channel impurity region 32 broad, any differences in threshold voltages between the first and second string selection transistors SST1 and SST2 may be minimized.

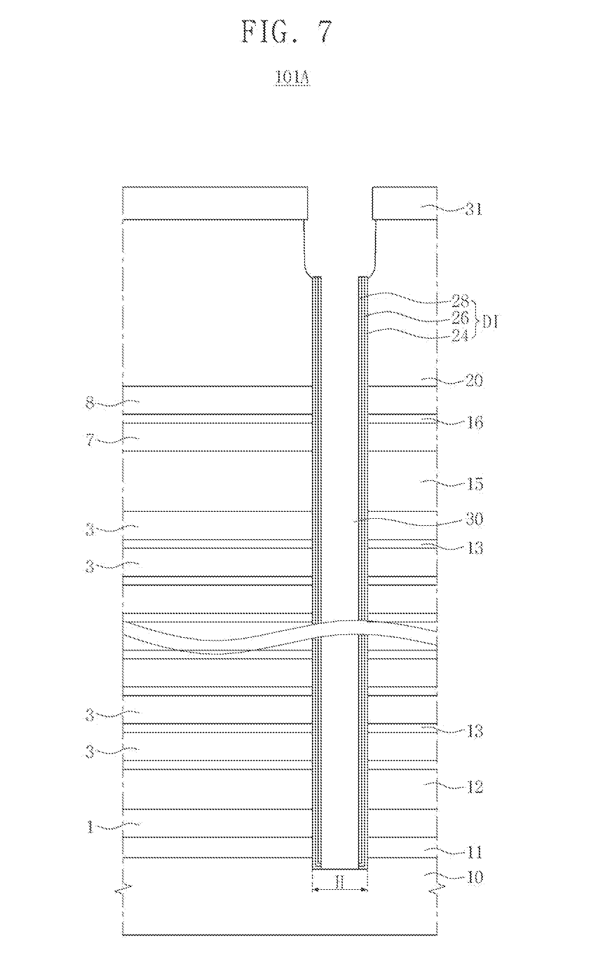

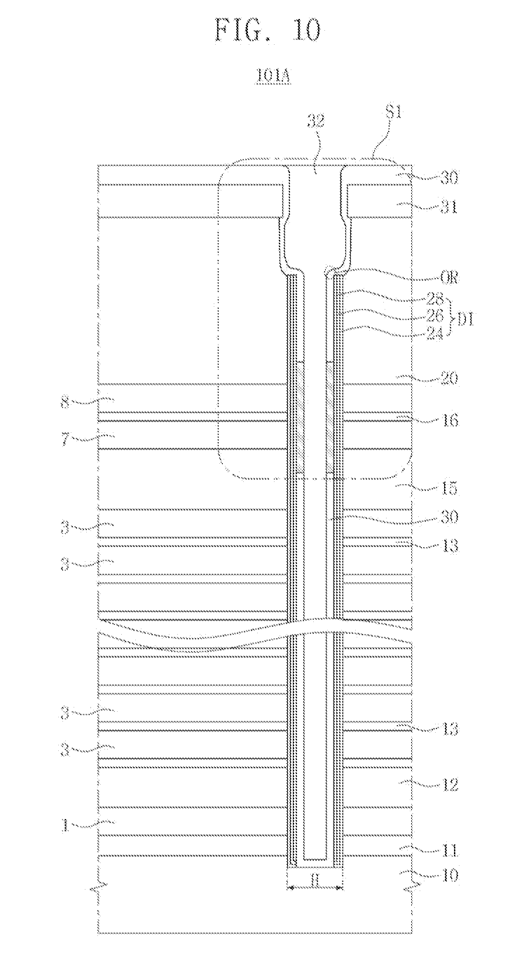

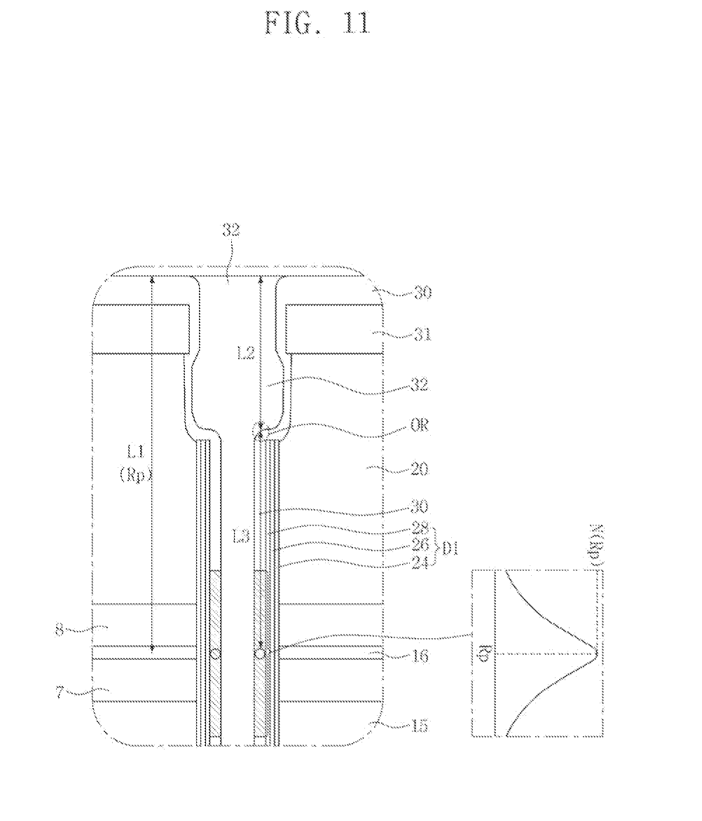

FIGS. 7 through 20 are diagrams illustrating a method of manufacturing the first exemplary embodiment of a semiconductor device in accordance with principles of inventive concepts. FIG. 11 is an enlarged view of a region S1 of FIG. 10.

Referring to FIG. 7, the method of manufacturing the semiconductor device in accordance with principles of inventive concepts may include forming insulating layers 11, 12, 13, 15, 16, and 20, sacrificial layers 1, 3, 7, and 8, a channel hole (H), and dielectric layers DI.

The insulating layers 11, 12, 13, 15, 16, and 20 and the sacrificial layers 1, 3, 7, and 8 may be alternately formed on a substrate 10. A first lower insulating layer 11 may be formed to be in contact with a top surface of the substrate 10. The first lower insulating layer 11 may partially cover the top surface of the substrate 10. A first lower sacrificial layer 1 may be formed on the first lower insulating layer 11. A second insulating layer 12 may be formed on the first lower sacrificial layer 1. The second insulating layer 12 may be thicker than the first lower insulating layer 11. 2ⁿ sacrificial layers 3 including a second sacrificial layer 3 through an n-th sacrificial layer may be formed. A fourth insulating layer 15 may be formed on the n-th sacrificial layer n. A first upper sacrificial layer 7 and a second upper sacrificial layer 8 may be formed on the fourth insulating layer 15. A fifth insulating layer 16 may be formed between the first upper sacrificial layer 7 and the second upper sacrificial layer 8. The insulating layers may have different thicknesses. A capping layer 20 may be formed on the second upper sacrificial layer 8.

The sacrificial layers 1, 3, 7, and 8 may be formed of a material having an etch selectivity with respect to the insulating layers 11, 12, 13, 15, and 16. For example, the insulating layers 11, 12, 13, 15, and 16 may be formed of silicon oxide (SiOₓ), and the sacrificial layers 1, 3, 7, and 8 may be formed of silicon nitride (SiNₓ). The capping layer 20 may be formed of silicon oxide (SiOₓ).

A channel hole H having a pillar shape may be formed through the sacrificial layers 1, 3, 7, and 8, the insulating layers 11, 12, 13, 15, 16, and 20, and the capping layer 20. The formation of the channel hole H may include forming a hard mask 31 to define a position of the channel hole H and alternately anisotropically etching the insulating layers 11, 12, 13, 15, 16, and 20, the sacrificial layers 1, 3, 7, and 8 and the capping layer 20 using a hard mask 31 as an etch mask. The hard mask 31 may include poly silicon. The surface of the substrate 10 may be over-etched and recessed. A recessed surface of the substrate 10 may correspond to a bottom surface of the channel hole H. An inner side surface of the channel hole H may be side surfaces of the insulating layers 11, 12, 13, 15, 16, and 20, the sacrificial layers 1, 3, 7, and 8, and the capping layer 20.

The dielectric layers DI may be formed on the bottom surface of the channel hole H, the inner side wall of the channel hole H. The dielectric layers DI may include a barrier layer 24, a charge trap layer 26, and tunneling layer 28. Each of the barrier layer 24, the charge trap layer 26, and the tunneling layers 28 may be formed using an atomic layer deposition (ALD) process or a chemical vapor deposition (CVD) process. The barrier layer 24 may include silicon oxide (SiOₓ), and the charge trap layer 26 may include silicon nitride (SiNₓ). The tunneling layer 28 may include silicon oxide or nitrogen (N)-doped silicon oxide.

An anisotropic etching process may be performed to partially remove the barrier layer 25, the charge trap layer 26, and the tunneling layers 28. The barrier layer 25, the charge trap layer, and the tunneling layer may be etched using a blank anisotropic etching process. Top and side surfaces of the hard mask 31 may be exposed. Top surfaces of the dielectric layers DI may be formed at a lower level than the top surface of the capping layer 20. One side of the barrier layer 24 may be in contact with the inner side surface of the channel hole H. One side of the charge trap layer 26 may be in contact with other side of the barrier layer 24. One surface of the tunneling layer 28 may be in contact with other side of the charge trap layer 26. The recessed surface of the substrate 10 may be exposed during the etching process.

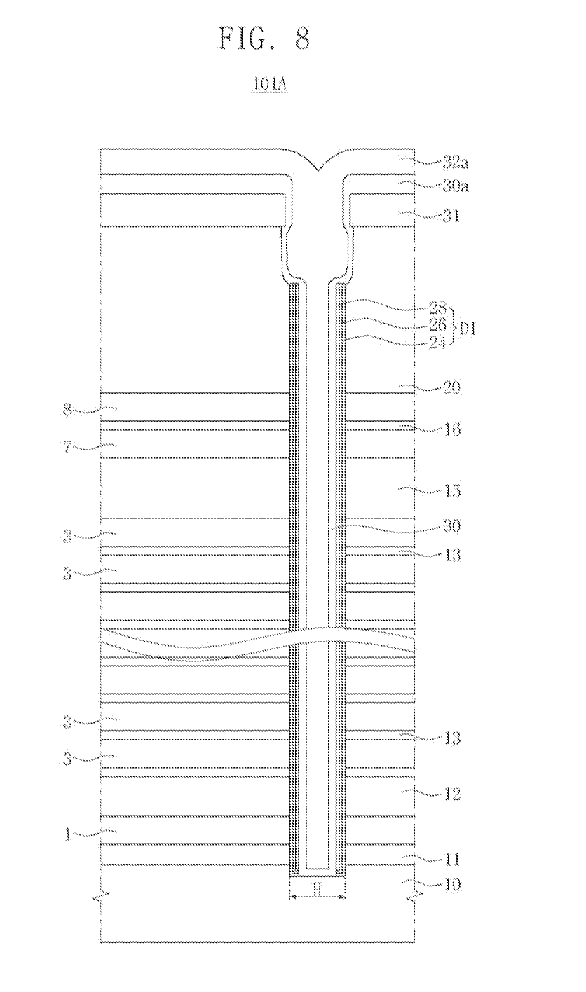

Referring to FIG. 8, a method of manufacturing a first exemplary embodiment of a semiconductor device in accordance with principles of inventive concepts may include forming a semiconductor layer 30a and gap fill layer 32a. The semiconductor layer 30a may be formed along the recessed surface of the substrate 10, other side surface of the tunneling layer 28, an exposed side surface of the capping layer 20, and exposed top and side surfaces of the hard mask 31. The semiconductor layer 30a may be formed using an ALD process or a CVD process. For example, the semiconductor layer 30a may include poly-Si. The semiconductor layer 30a may be formed to be a thickness of from ⅕ to 1/50 the diameter of the channel holes H. A gap fill layer 32a may be formed to fill the channel holes H covered with the semiconductor layer 30a. The gap fill layer 32a may be formed using an ALD process. The gap fill layer 32a may be formed to cover the exposed top and side surfaces of the semiconductor layer 30a. For instance, the gap fill layer 32a may include silicon oxide (SiOₓ).

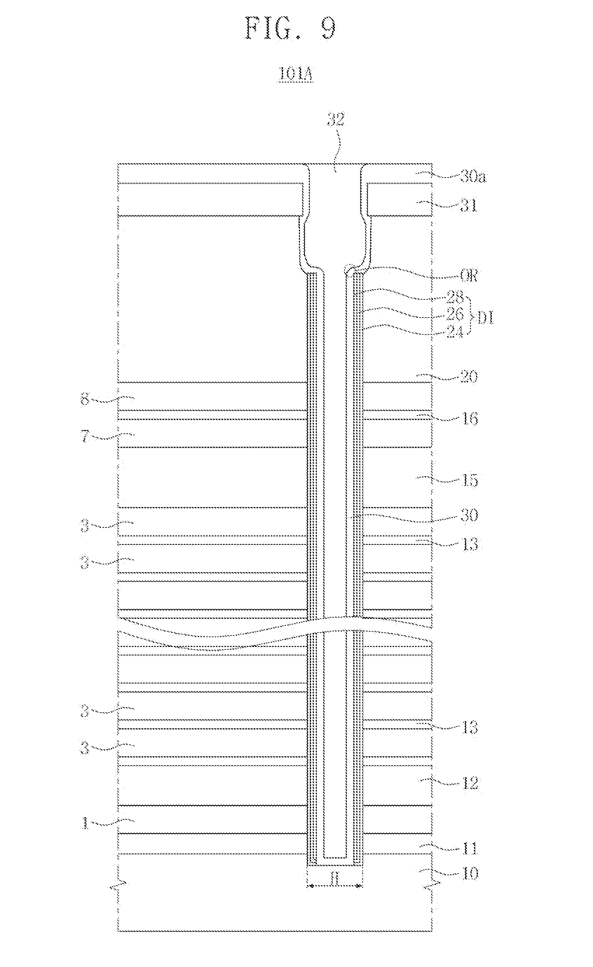

Referring to FIGS. 8 and 9, a method of manufacturing a first exemplary embodiment of a semiconductor device in accordance with principles of inventive concepts may include forming a gap fill pattern 32.

The gap fill pattern 32 may be formed by partially removing the gap fill layer 32a covering the semiconductor layer 30a. The partially removal of the gap fill layer 32a may include a planarization process for exposing a top surface of the semiconductor layer 30a. For example, the planarization process may include a chemical mechanical polishing (CMP) process. CMP slurry may be used during the CMP process as a means to remove the gap fill layer 32a. The CMP slurry may include a polishing particle, an etchant, a surfactant, and so one.

The CMP process may use a different etchant according to the quality of a layer to be polished. When the gap fill layer 32a includes an oxide layer, hydrofluoric acid (HF) or a buffer oxide etchant (BOE) may be used as an etchant. The surfactant may include ammonium fluoroalkyl sulfonamides (S1), perfluoroalkyl sulfonates (S2), or polyethylene glycols (S3) may be used as a surfactant.

The CMP slurry may be coated on the top surface of the gap fill layer 32a by a spin coating process. In the spin coating process, the thickness of the coated the CMP slurry may be adjusted by controlling the viscosity of the CMP slurry or revolutions per minute (rpm) of the substrate 10. A top surface of the semiconductor layer 30a may be exposed using the CMP process. As a result of the CMP process, the top surface of the semiconductor layer 30a and the top surface of the gap fill pattern 32 may be formed at a same level. An overlap region OR in which the channel layer and the gap fill pattern are overlapped may be formed within the channel hole. The gap fill pattern 32 may vertically overlap the semiconductor layer 30a at the overlap region OR. The overlap region OR may be formed at the position adjacent to the top surfaces of the dielectric layers DI.

FIG. 11 is an enlarged cross-sectional view of a portion S1 of FIG. 10. A method of manufacturing a first exemplary embodiment of a semiconductor device 101A in accordance with principles of inventive concepts may include forming a channel impurity region 23. The formation of the channel impurity region 23 may include implanting p-type impurity in the channel layer 30. The channel impurity region 23 may be formed in a region of a channel layer 30 corresponding to sides of the first and second upper sacrificial layers 7 and 8 and the fifth insulating layer 16. The top end of the channel impurity region 32 may be formed at a higher level than the top surface of the second upper sacrificial layer 8, and the bottom end of the channel impurity region 32 may be formed at a lower level than the bottom surface of the first upper sacrificial layer 7.

The p-type impurity may include boron (B), gallium (Ga), or indium (In), for example. Implanted p-type impurities may sequentially pass through the gap fill pattern 32 and the channel layer 30 at the vertically overlap region OR during the p-type impurity implantation process.

Referring to FIG. 11, in exemplary embodiments in accordance with principles of inventive concepts, an impurity concentration distribution in the channel impurity region 30 may follow a Gaussian distribution. The Gaussian distribution may be expressed as a probability distribution about the stop position of implanting ions. The Gaussian distribution may be denoted by an ion concentration variation N(x) according to a variation of the ion stop position (x) of the implanting ions. An average penetration depth of the implanting ions may be denoted as an ion projection range Rp, and a standard deviation of the ion projection range Rp may be denoted as ΔRp.

With the stop position(x) given as the ion projection range Rp, the ion concentration N(Rp) corresponds with the maximum ion concentration N(max) and the ion concentration distribution may be symmetrically reduced in a vertical direction with respect to the maximum ion concentration N(max) in the channel impurity region. That is, the concentration distribution may be characterized as a vertical Gaussian distribution with a maximum coinciding with the ion projection range Rp.

As illustrated in the exemplary embodiment of FIG. 11 L1 is the distance by which ions are transmitted through the gap fill pattern 32 and the channel layer 30, which corresponds to the ion projection range Rp. L2 is the distance by which ions are transmitted through the gap fill pattern 32, and L3 is the distance by which ions are transmitted through the channel layer 30.

In exemplary embodiments, the ion projection range Rp(L1) may be positioned between the first sacrificial layer and the second sacrificial layer. For example, ion projection range Rp can be from about 2700 to about 4000 Å. To improve threshold voltage variation characteristics of the string selection transistors (string selection transistors 1 and 2) SST1 and SS2 in FIG. 1, the channel impurity region 23 may be formed in the channel layer corresponding to the side surfaces of the first and second upper sacrificial layers 7, 8. As a result, the Gaussian distribution may have a broad distribution shape in the channel impurity layer.

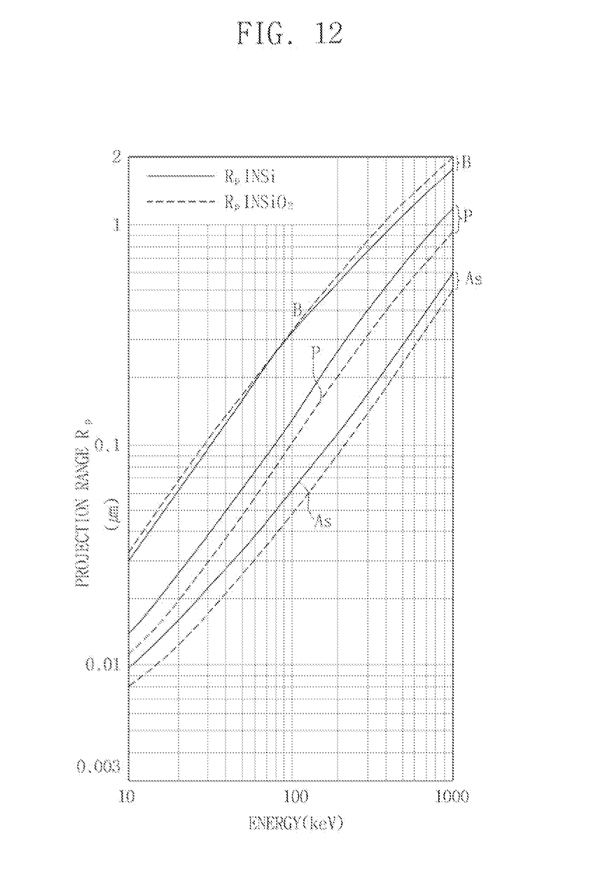

The ion projection range Rp (of the p-type impurity) may depend on ion injection energy and/or the kind of ion implantation medium. FIG. 12 is a graph of a projection range Rp of ions relative to an ion injection energy and ion implantation medium. In FIG. 12, the x-axis shows ion injection energy and the Y-axis shows the ion projection range Rp according to the ion injection energy. As mentioned above, the ion projection range Rp may be the average penetration depth of implanted ions. A solid line shows a case in which an ion implantation medium is silicon (Si), and a dotted line shows a case in which an ion implantation medium is silicon oxide (SiO₂). In the case of boron (B), an ion projection range Rp varies little according to whether the ion implantation medium is silicon or silicon oxide. When other ions such as phosphorus (P) or arsenic (As) are implanted, the ion projection range Rp varies more significantly depending on whether the ion implantation medium is silicon or silicon oxide. In exemplary embodiments in accordance with principles of inventive concepts, the implanted ions for the formation of the channel impurity region 23 may penetrate through a plurality of media (for example, two different media). In an exemplary embodiment, one medium is the gap fill pattern 32 including silicon oxide, and other medium is the channel layer 30 including poly-Si. In a method of manufacturing a semiconductor device in accordance exemplary embodiments of inventive concepts, an example in which boron (B) is used will be described.

Table 1 shows an ion projection range Rp of boron and a standard deviation ΔRp in ion projection range relative to an energy amount when a projection medium is poly-Si.

TABLE 1

| | |
|---|---|
| | Medium (Si) |
| Energy amount | Implanted atoms: boron (B) |

| (KeV) | Rp(μm) | ΔRp(μm) |
|---|---|---|
| 1 | 0.0033 | 0.0017 |
| 3 | 0.0100 | 0.0051 |
| 5 | 0.0167 | 0.0086 |
| 7 | 0.0233 | 0.0120 |
| 10 | 0.0333 | 0.0171 |
| 15 | 0.0498 | 0.0227 |
| 20 | 0.0652 | 0.0283 |
| 25 | 0.0825 | 0.0327 |
| 30 | 0.0987 | 0.0371 |
| 35 | 0.1145 | 0.0407 |
| 40 | 0.1302 | 0.0443 |
| 45 | 0.1455 | 0.0474 |
| 50 | 0.1608 | 0.0504 |
| 60 | 0.1903 | 0.0556 |
| 70 | 0.2188 | 0.0601 |
| 80 | 0.2465 | 0.0641 |
| 90 | 0.2733 | 0.0677 |
| 100 | 0.2994 | 0.0710 |
| 110 | 0.3248 | 0.0739 |
| 120 | 0.3496 | 0.0766 |
| 130 | 0.3737 | 0.0790 |
| 140 | 0.3794 | 0.0813 |

Referring to Table 1, for example, an ion implantation process may be performed at an energy of about 70 keV so that the ion projection range Rp can be adjusted to about 0.22 μm. At this energy the standard deviation ΔRp is about 0.06 μm. An ion implantation process may be performed at an energy of about 110 keV so that the ion projection range Rp can be adjusted to about 0.032 μm, at which energy the standard deviation ΔRp is about 0.073 μm. In exemplary embodiments, the standard deviation ΔRp may be increased along with increasing ion projection range Rp and the ion projection range Rp may be increased with increased ion injection energy. In other words, in accordance with principles of inventive concepts, a Gaussian ion distribution may be broadened by increasing the distance/or depth of the ion projection range Rp(L1) and, as previously described, a broader Gaussian ion distribution may substantially eliminate any variation in threshold voltages among different string selection transistors.

Referring to FIG. 11, to increase the ion projection range Rp(L1), the ion implantation process may be performed without removing the hard mask 31 and the channel layer 30 on the hard mask 31. A thickness L2 of the gap fill pattern 32 on the vertically overlap region OR may be indirectly controlled by adjusting the thicknesses of the hard mask 31 and the channel layer disposed on the top surface of the hard mask 31. For example, the thickness L2 of the gap fill pattern 32 on the vertically overlap region OR may be increased by forming thicker the hard mask 31 and the channel layer disposed on the top surface of the hard mask 31. As a result, the ion projection region Rp(L1) may be increased.

Referring to Table 1, in a method of manufacturing a semiconductor device according to embodiments of inventive concepts, the implant energy may be controlled to be in the range of from about 90 to about 130 KeV so that an ion projection range Rp can be about 2700 to 4000 Å. If the implant energy were less than about 90 KeV, the standard deviation ΔRp in the ion projection range Rp could so narrow that it may be difficult to reduce the differences in threshold voltages between two string selection transistors SST1 and SST2. On the other hand, if the implant energy were to exceed about 130 KeV, the resultant higher threshold voltages could cause excess energy consumption.

In a method of manufacturing a semiconductor device in accordance with an exemplary embodiment in accordance with principles of inventive concepts, the boron ions may be distributed as a broad Gaussian distribution. The broad Gaussian distribution may be obtaining by adjusting the ion projection range Rp as mentioned above. Therefore, the channel impurity region 23 including the boron ions is disposed corresponding to the second upper sacrificial layer 8 and the first upper sacrificial layer 7. As a result, the difference of the threshold voltages of the first and second string selection gate electrodes 53 and 54 may be reduced.

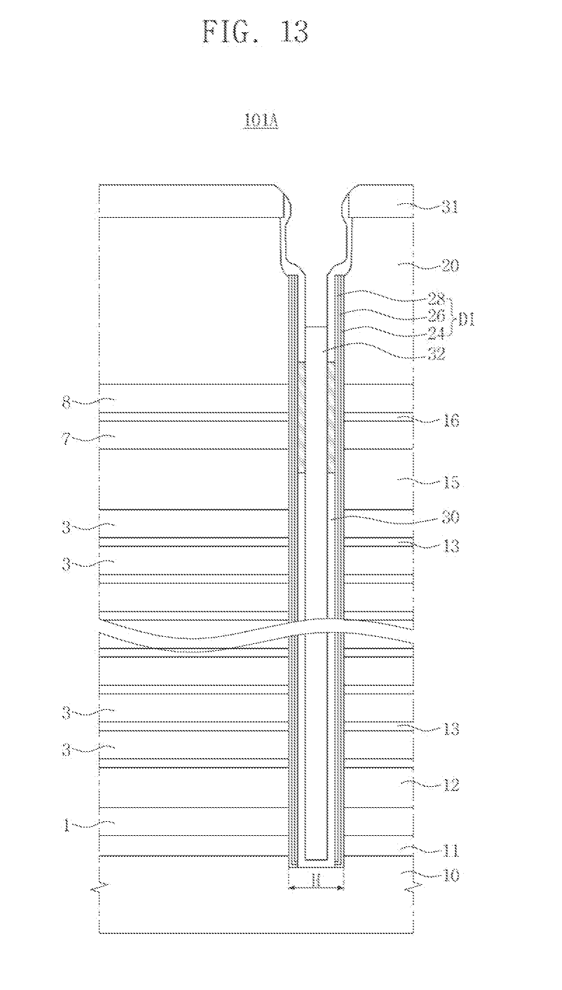

Referring to FIG. 13, a method of manufacturing the first exemplary embodiment of a semiconductor device in accordance with principles of inventive concepts may include recessing a top surface of the gap fill pattern 32. The top surface of the gap fill pattern 32 may be recessed using an etchback process. A recessed surface of the gap fill pattern 32 may be formed at a lower level than the top surfaces of the dielectric layers DI, and may be formed at a higher level than a top end of the channel impurity region 23.

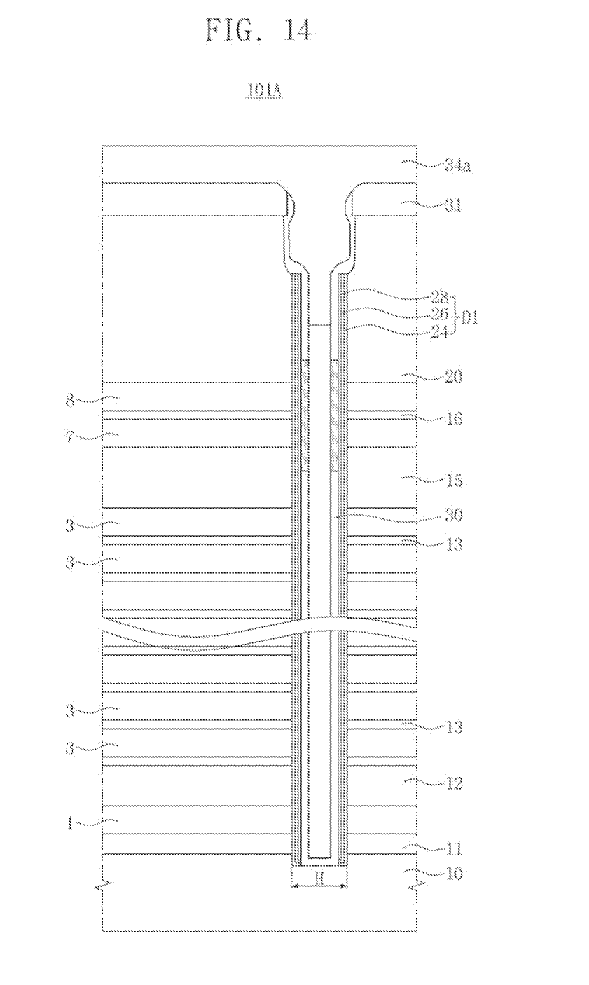

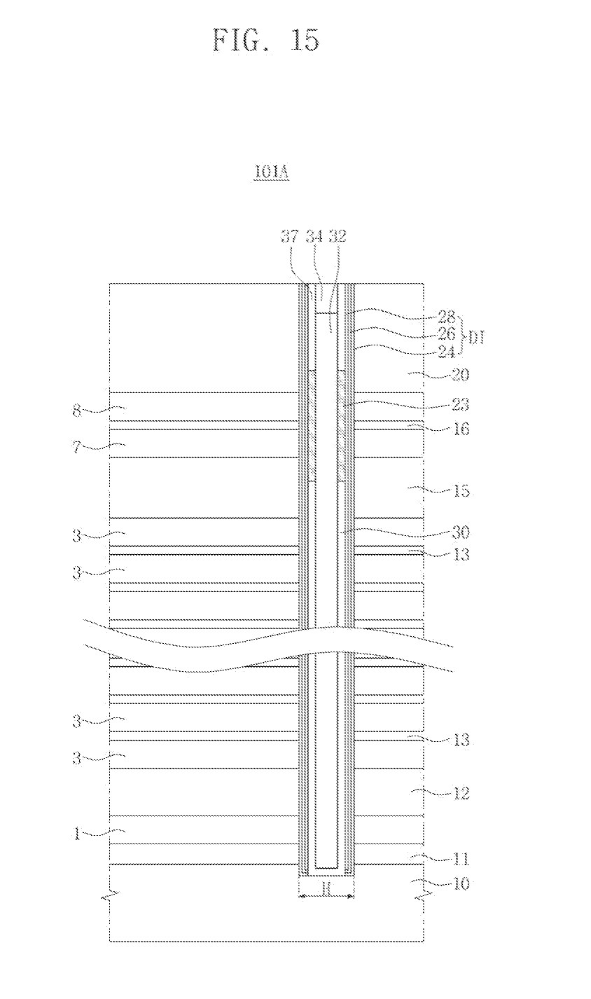

Referring to FIG. 14, a method of manufacturing a first exemplary embodiment of a semiconductor device in accordance with principles of inventive concepts may include forming contact layer 34a. The contact layer 34a may be formed along the recessed surface of the gap fill pattern 32, the exposed side surfaces of the channel layer 30, and a top surface of the hard mask 31. For example, the contact layer 34a may include carbon (C)-doped poly-Si. Referring to FIGS. 14 and 15, a method of manufacturing a first exemplary embodiment of a semiconductor device in accordance with principles of inventive concepts may include forming a contact pad 34. The contact pad 34 may be formed by partially removing the contact layer using a planarization process. After the planarization process, the top surface of the capping layer 20 may be exposed. Top surfaces of the contact pad 34, the channel layer 30, the dielectric layer DI, and the capping layer 20 may be formed at a same level. For example, the planarization process may include a CMP process.

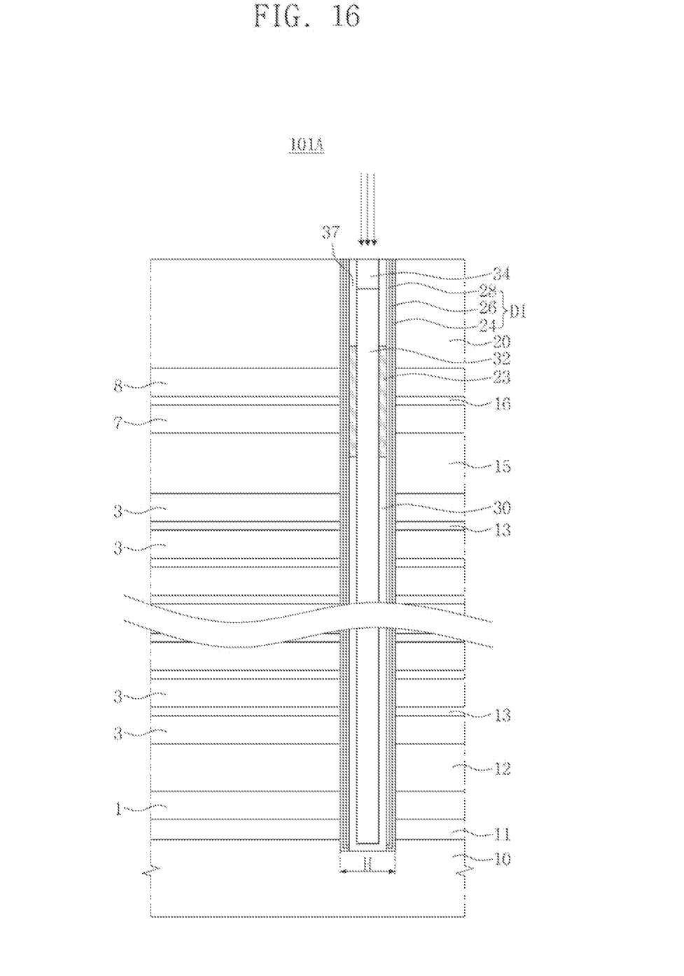

Referring to FIG. 16, a method of manufacturing a first exemplary embodiment of a semiconductor device in accordance with principles of inventive concepts may include performing an ion implantation process on the contact pad 34. N-type impurities may be implanted into the contact pad 34 using the ion implantation process. The depth to which the n-type impurities are implanted into the contact pad 34 may be controlled by an ion implantation energy. The n-type impurities implanted using the ion implantation process may be diffused the channel later 30 using subsequent annealing processes. A portion of the channel layer 30 in which the n-type impurities are diffused may be drain region 37. The contact pad 34 may be referred to as an impurity ion implantation region, while the drain region 37 may be referred to as an impurity ion diffusion region. Due to the ion implantation process and the annealing process, a concentration distribution gradient may occur between the contact pad 34 and the drain region 37. The contact pad 34 may have a higher n-type impurity concentration than the drain region 37. For example, the n-type impurities may be phosphorus (P) or arsenic (As).

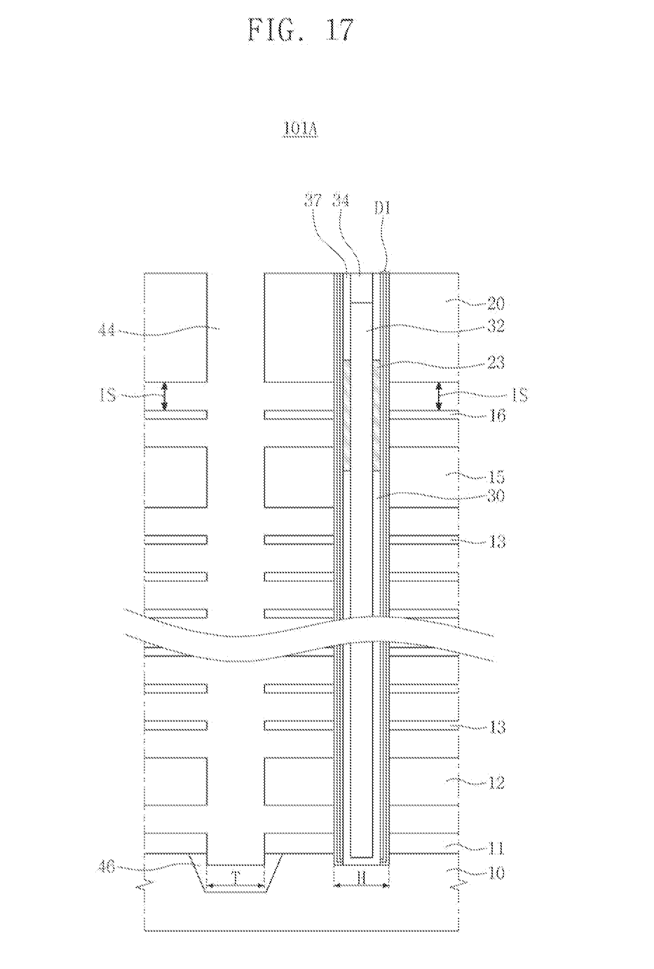

Referring to FIG. 17, a method of manufacturing a first exemplary embodiment of a semiconductor device in accordance with principles of inventive concepts may include forming a trench T and interlayer spaces IS.

The formation of the trench T may include anisotropically etching the capping layer 20, the sacrificial layers 1, 3, 7, and 8, and the insulating layers 11, 12, 13, 15, and 16 until the top surface of the substrate 10 is exposed. The interlayer spaces IS may be formed by removing the sacrificial layers 1, 3, 7, and 8 disposed between the insulating layers 11, 12, 13, 15, 16, and 20 through the trench T to form spaces. The etching process for removing the sacrificial layers 1, 3, 7, and 8 may include an isotropic etching process including a wet etching process or a chemical dry etch (CDE) process. Phosphoric acid (H₃PO₄) may be used as an etchant used in a wet etching process. The etching process may further include a cleaning process using SC-1 (Standard cleaning 1).

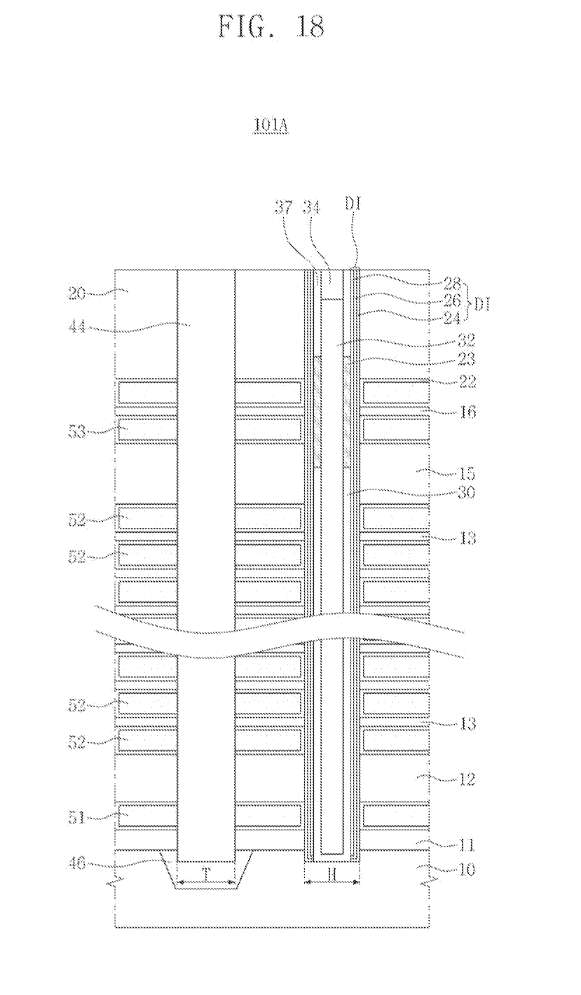

Referring to FIG. 18, a method of manufacturing a first exemplary embodiment of a semiconductor device in accordance with principles of inventive concepts may include forming blocking layers 22, gate electrodes 51, 52, 53, and 54, and a device isolation layer 44.

The blocking layers 22 may be in contact with the exposed surfaces of the barrier layer 24 and the insulating layers 11, 12, 13, 15, 16, and 20. The gate electrodes 51, 52, 53, and 54 may be filled in the interlayer spacers IS. The gate electrodes 51, 52, 53, and 54 may be in contact with exposed surfaces of the blocking layers. As described above, the gate electrodes 51, 52, 53, and 54 may include the ground selection gate electrode 51, the cell gate electrodes 52, and the string selection gate electrodes 53 and 54. The string selection gate electrodes 53 and 54 may have first and second string selection gate electrodes 53 and 54. The top end of the ion impurity region 23 may be formed at a higher level than the top surface of the second string selection gate electrode 54 and the bottom end of the ion impurity region 23 may be formed at a lower level than the bottom surface of the first string selection gate electrode 53. The device isolation layer 44 may be formed in the trench T.

The blocking layer 22 may include a metal oxide having a larger work function or higher dielectric constant than the barrier layer 24. For example, the metal oxide may include aluminum oxide (Al₂O₃) or hafnium oxide (HfO₂). The gate electrodes 51, 52, 53, and 54 may include a doped silicon, a metal such as tungsten (W), copper (Cu), or aluminum (Al), a conductive metal nitride such as titanium nitride (TiN) or tantalum nitride (TaN), a conductive metal-semiconductor compound such as a metal silicide, or a transition metal such as titanium (Ti) or tantalum (Ta).

The device isolation layer 44 may include silicon oxide (SiOx).

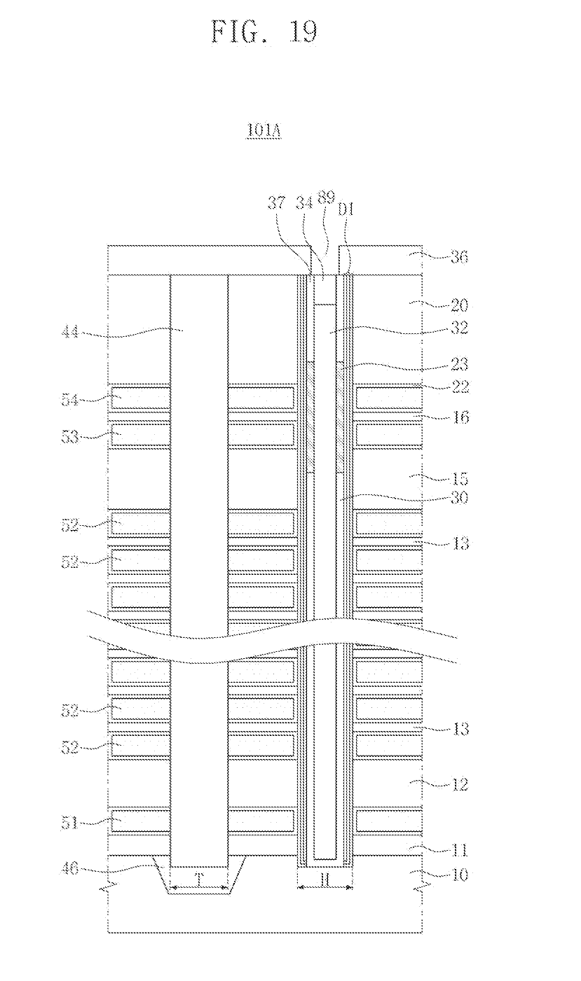

Referring to FIG. 19, a method of manufacturing a first exemplary embodiment of a semiconductor device in accordance with principles of inventive concepts may include forming an interlayer insulating layer 36 and a via 89 through the interlayer insulating layer 30.

The interlayer insulating layer 30 may cover the exposed top surfaces of the capping layer 20, the dielectric layers DI, and the channel layer 30. The via 89 may be formed by selectively remove the interlayer insulating layer 36. The top surface of the contact pad 34 may be exposed through the via 89.

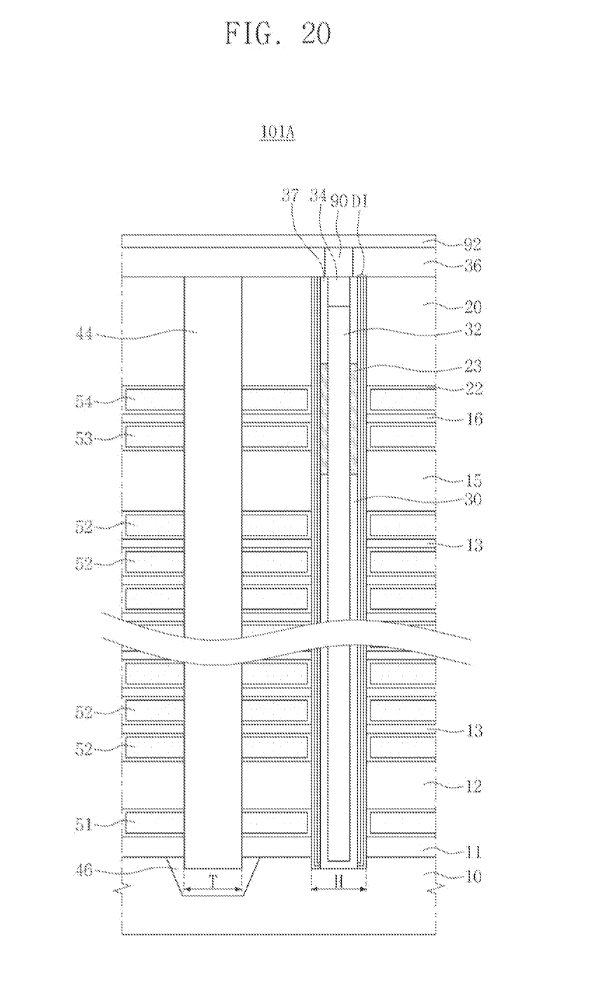

Referring to FIGS. 19 and 20, a method of manufacturing a second exemplary embodiment of a semiconductor device in accordance with principles of inventive concepts may include a contact plug 90 and a conductive line 92.

The contact plug 90 may be formed to fill the via (89) and may be in contact with the top surface of the contact pad 34. A conductive line 92 may be formed to be electrically connected to the contact plug 90. For example, the contact plug 90 and the conductive line 92 may include a metal, a metal compound, or a metal silicide.

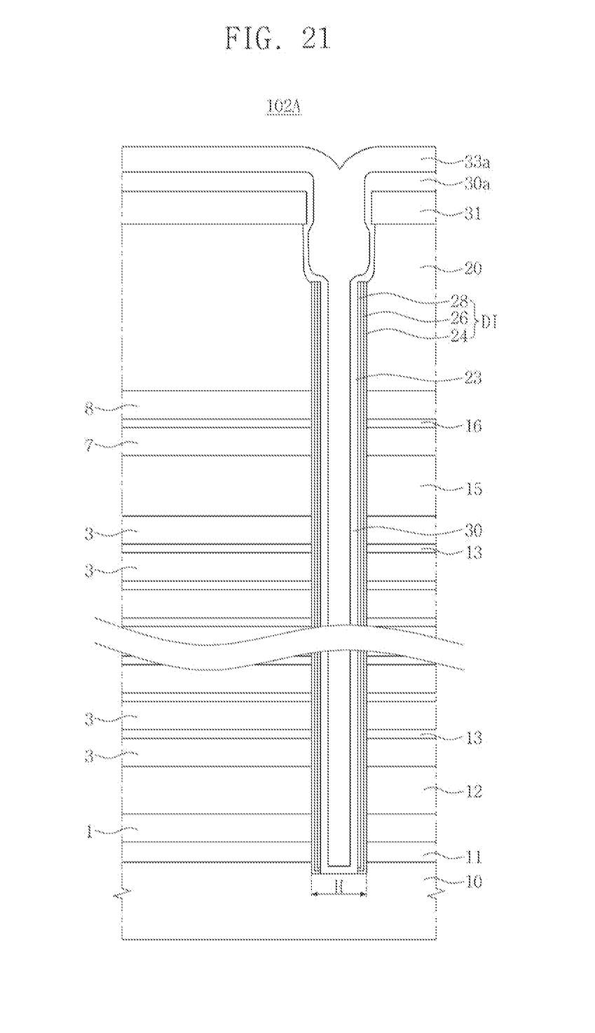

FIGS. 21 through 34 are diagrams illustrating a process of manufacturing a second exemplary embodiment of a semiconductor device in accordance with principles of inventive concepts.

Referring to FIG. 21, a method of manufacturing a second exemplary embodiment of a semiconductor device 102A in accordance with principles of inventive concepts include forming a semiconductor layer 30a and a lower gap fill layer 33a. The semiconductor layer 30a may be in contact with a side surface of the dielectric layer DI, a recessed surface of the substrate 10, an upper side surface of the capping layer 33a, and top and side surfaces of the hard mask 31. The lower capping layer 33a may be in contact with a surface of the semiconductor layer 30a. The semiconductor layer 30a may include poly-Si. The lower capping layer 33a may include a silicon oxide (SiO2)

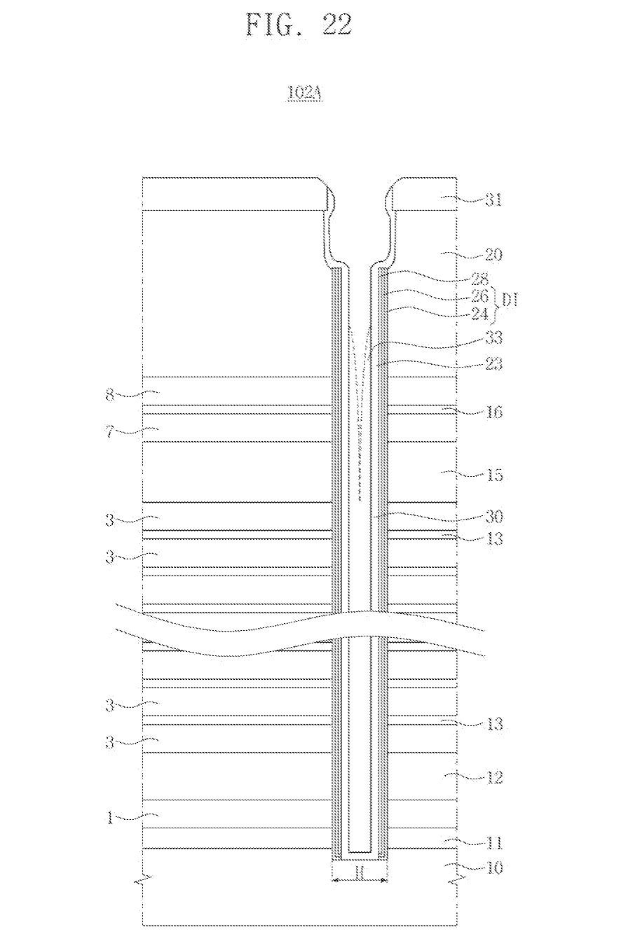

Referring to FIGS. 21 and 22, a method of manufacturing a second exemplary embodiment of a semiconductor device 102A in accordance with principles of inventive concepts include forming a channel layer 30 and a lower gap fill pattern 33.

The lower gap fill pattern 33 may be formed by partially remove a lower gap fill layer 33a using an etchback process. A center of a top surface of the lower gap fill pattern 33 may be formed at a lower level than a bottom surface of the first upper sacrificial layer 7. The both ends of the top surface of the lower gap fill pattern 33 may be formed at a higher level than a top surface of the second upper sacrificial layer 8. During the etchback process, the channel layer 30 may be formed by etching an upper portion of the semiconductor layer 30a disposed on the hard mask 31. The channel layer 30 may be in contact with a side surface of the dielectric layer DI.

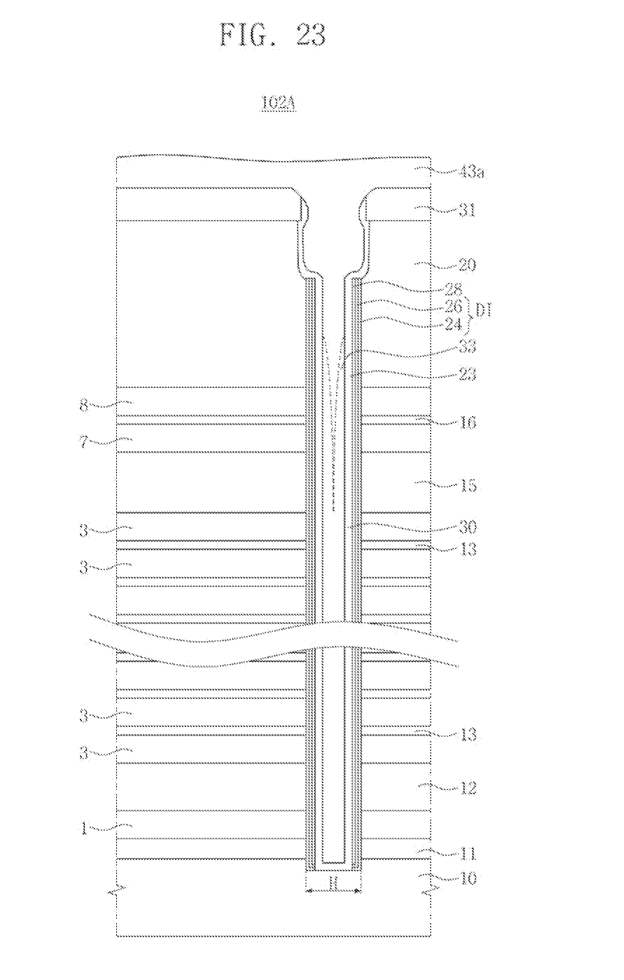

Referring to FIG. 23, a method of manufacturing a second exemplary embodiment of a semiconductor device 102A in accordance with principles of inventive concepts include forming an upper gap fill layer 43a. An upper gap fill layer 43a may be formed along the top surface of the lower gap fill pattern 33, a side surface of the channel layer 30, and top and side surfaces of the hard mask 31. The upper gap fill pattern 43 may be formed using an ALD process. For example, the upper gap fill layer 43a may include an insulating material, which may include silicon oxide (SiO_{X}). The upper gap fill layer 43a may be denser than the lower gap fill pattern 33.

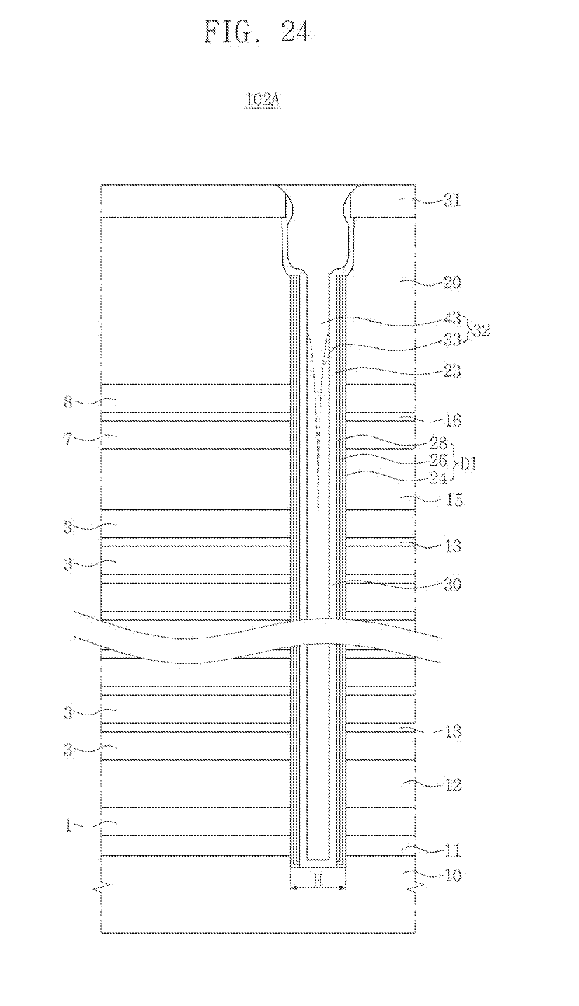

Referring to FIGS. 23 and 24, a method of manufacturing a second exemplary embodiment of a semiconductor device 102A in accordance with principles of inventive concepts include forming an upper gap fill pattern 43. The upper gap fill pattern 43 may be formed by removing a portion of the upper gap fill layer 33a covering the hard mask 31. The process of removing the upper gap fill layer 43a may include a planarization process for exposing the surface of the hard mask 31. For example, the planarization process may include a CMP process. A top surface of the hard mask 31 may be exposed after the CMP process. Since the CMP process is performed until the top surface of the hard mask 31 is exposed. The above-described process may be referred to as a poly-stop CMP (PSC) process. A top surface of the upper gap fill pattern 43 may be at a same level with a top surface of the hard mask 31. The upper gap fill pattern 43 may be denser than the lower gap fill pattern 33.

A gap fill pattern 32 may collectively refer to the lower gap fill pattern 33 and the upper gap fill pattern 43

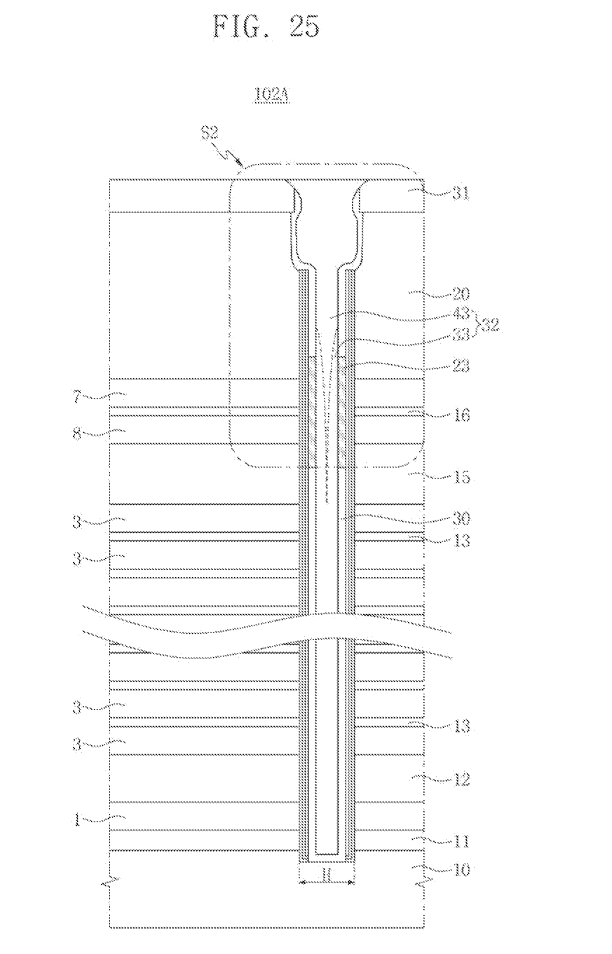

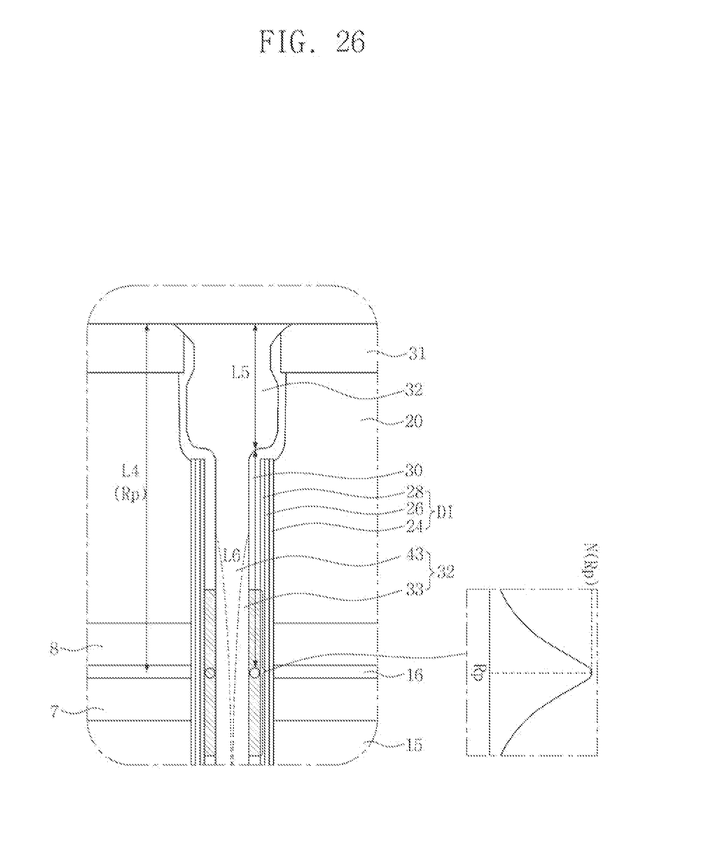

FIG. 26 is an enlarged cross-sectional view of a portion S2 of FIG. 25

Referring to FIGS. 25 and 26, a method of manufacturing a second exemplary embodiment of a semiconductor device 102A in accordance with principles of inventive concepts include forming an impurity channel layer 23.

The formation of the channel impurity region 23 may include implanting p-type impurity in the channel layer 30 corresponding to the first and second upper sacrificial layers 7 and 8 and the fifth insulating layer 16. During the ion implantation process, the p-type impurity ions may pass through the upper gap fill pattern 43 and stop in the channel layer 30.

The p-type impurity may include boron (B). The upper gap fill pattern 43 may include silicon oxide (SiOx), and the channel layer 30 may include poly-Si.

The top end of the channel impurity region 23 may be formed at a higher level than the top surface of the second upper sacrificial layer 8. The bottom end of the channel impurity region 23 may be formed at a lower level than the bottom surface of the first upper sacrificial layer 7.

The concentration distribution of the p-type impurity ions of the channel impurity region may have a broad Gaussian distribution. A concentration distribution of the p-type impurity ions in the channel impurity region 23 may be symmetrically distributed in a vertical direction with respect to the highest concentration point Rp. In this exemplary embodiment, the ion projection range Rp in the channel impurity region may be indicated by L4. L4 may be expressed as the sum of a distance L5 by which ion beams pass through the upper gap fill pattern 43 and a distance L6 by which the ion beams pass through the channel layer 30 during the ion implantation process. The distance L4 may be controlled by varying a thickness of the hard mask 31. When a desired ion projection range Rp is from about 3000 to about 4000 Å, if the distance L4 is smaller than the desired ion projection range Rp, the thickness of the hard mask 31 may be formed thicker in order to obtain a length of the distance L4 corresponding to the desired ion projection range Rp.

The Gaussian distribution may have a broad shape by controlling the ion projection range Rp using the method as described above. Therefore, the channel impurity region 23 may be formed along the side surfaces of the first and second upper sacrificial 7 and 8, threshold voltage characteristics of the first and second string selection transistors SST1 and SST2 may be improved. That is, as previously described, a broad Gaussian ion distribution in accordance with principles of inventive concepts may substantially eliminate variations in threshold values of string selection transistors SST1 and SST2.

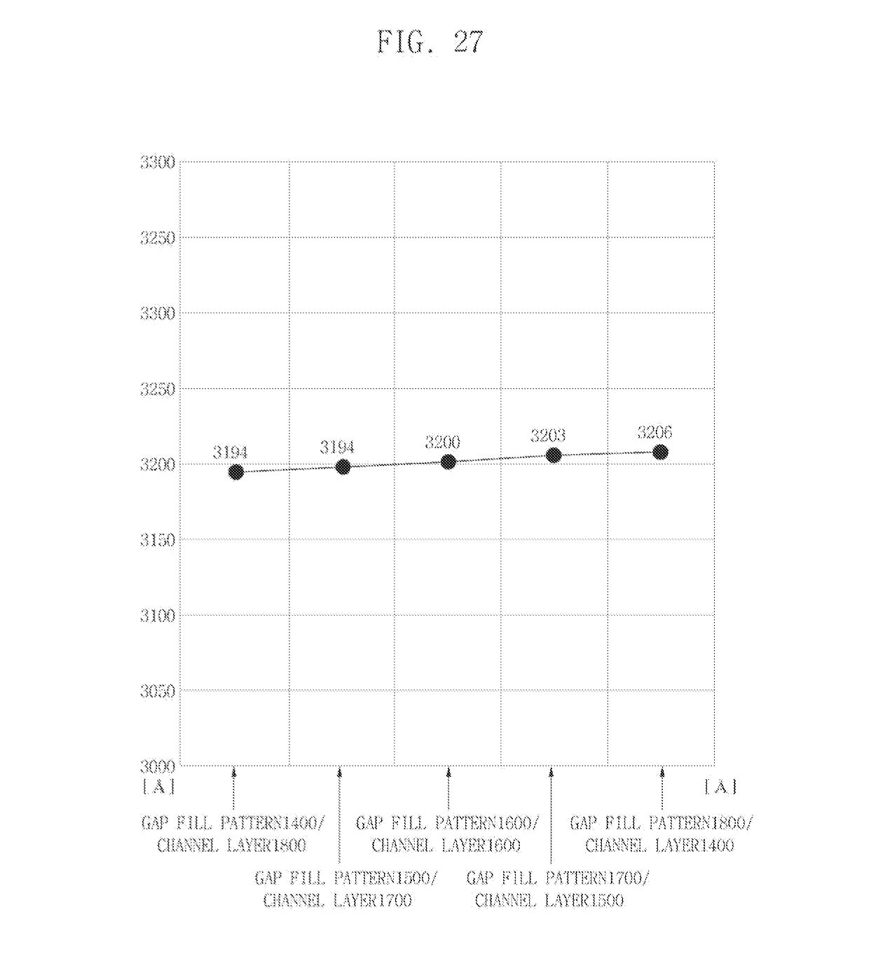

However, the lower gap fill pattern 33 may be over-etched due to process differences. If the lower gap fill pattern 33 is over-etched, the channel layer 30 may be etched. When the channel layer 30 is etched, a distance by which the ion beams penetrate the upper gap fill pattern 43 may vary. When the distance by which the ion beams penetrate the upper gap fill pattern 43 varies, the distance L6 by which the ion beams penetrate the channel layer 30 may vary according to the distance L5 by which the ion beams penetrate the upper gap fill pattern 43. Nevertheless, an ion projection range Rp in accordance with principles of inventive concepts may be ensured, as substantiated by the experimental results depicted in the graph of FIG. 27, which plots an ion projection range Rp versus a variation in the distance L5. The abscissa denotes the thickness of an upper gap fill pattern 43 and the thickness of a channel layer 30, and the ordinate denotes a projection range Rp of ion beams. The implanted impurities are Boron (B). Ion injection energy of the ion beam may be limited to about 90 KeV during an ion implantation process. With a desired ion projection range of about 3200 Å the thickness of the upper gap fill pattern 43 was varied from about 1400 Å to about 1800 Å.

From FIG. 27, it can be seen that when the thickness of the channel layer 30 varied in the range of about 1800 Å to about 1400 Å, the difference in ion projection range Rp varied in the range of from about 3194 Å to about 3206 Å. Accordingly, even if there is a difference in the degree of etching during the removal of a lower gap fill pattern 33, an ion projection range Rp in accordance with principles of inventive concepts may be ensured.

Referring to FIG. 28, a method of manufacturing a second exemplary embodiment of a semiconductor device in accordance with principles of inventive concepts may include recessing a top surface of the upper gap fill pattern 43. The top surface of the upper gap fill pattern 34 may be recessed using an etchback process. The top surface of the upper gap fill pattern 43 may be formed at a lower level than the top surface of the dielectric layers DI, and may be formed at a higher level than the top end of the channel impurity region 23.

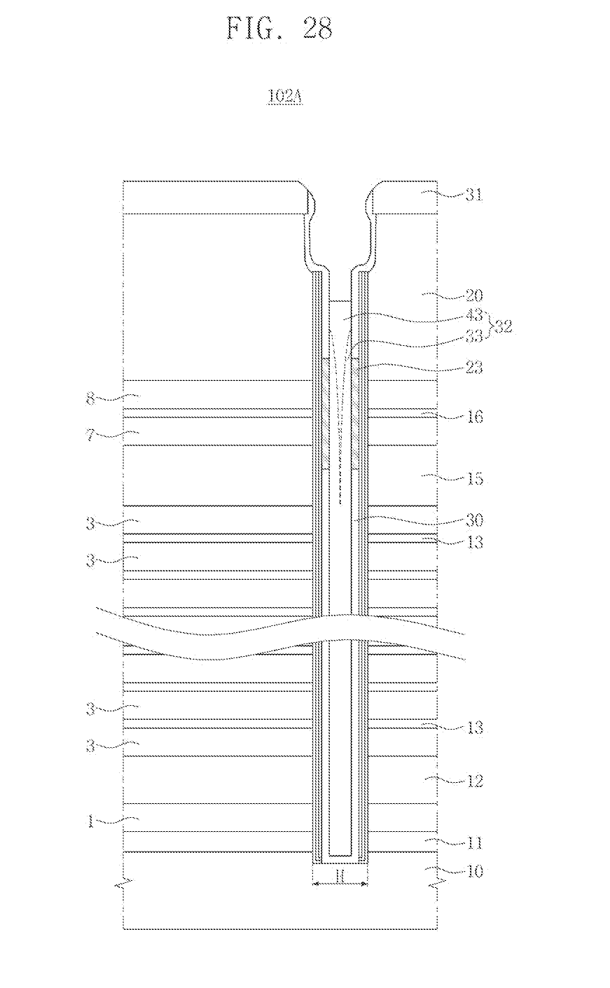

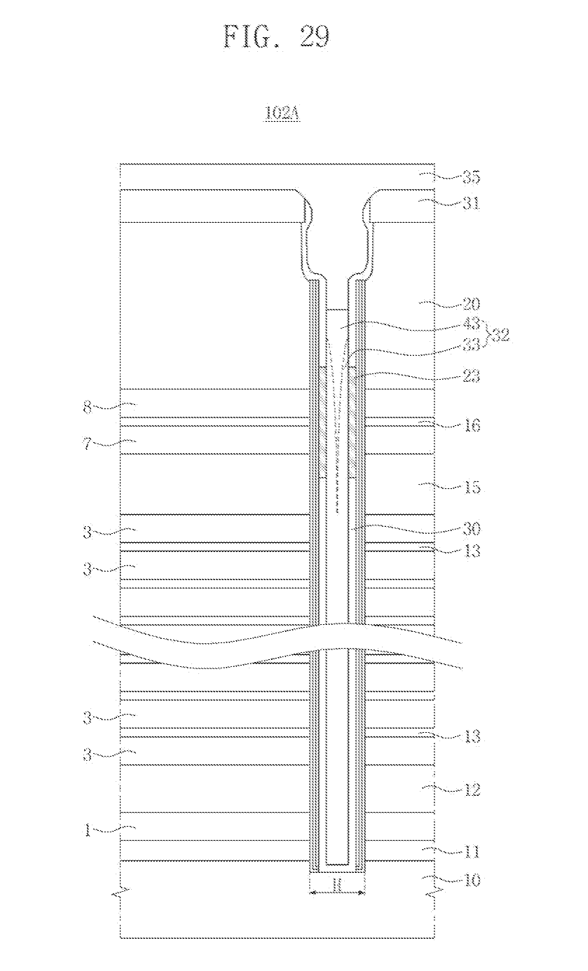

Referring to FIG. 29, a method of manufacturing a second exemplary embodiment of a semiconductor device in accordance with the exemplary embodiment the embodiments of the inventive may include forming a contact layer 35. The contact layer 35 may be formed along the top surface of the upper gap fill pattern 43, the side surface of the channel layer 30, and the top surface of the hard mask 31. For example, the contact layer 35 may contain C-doped poly-Si.

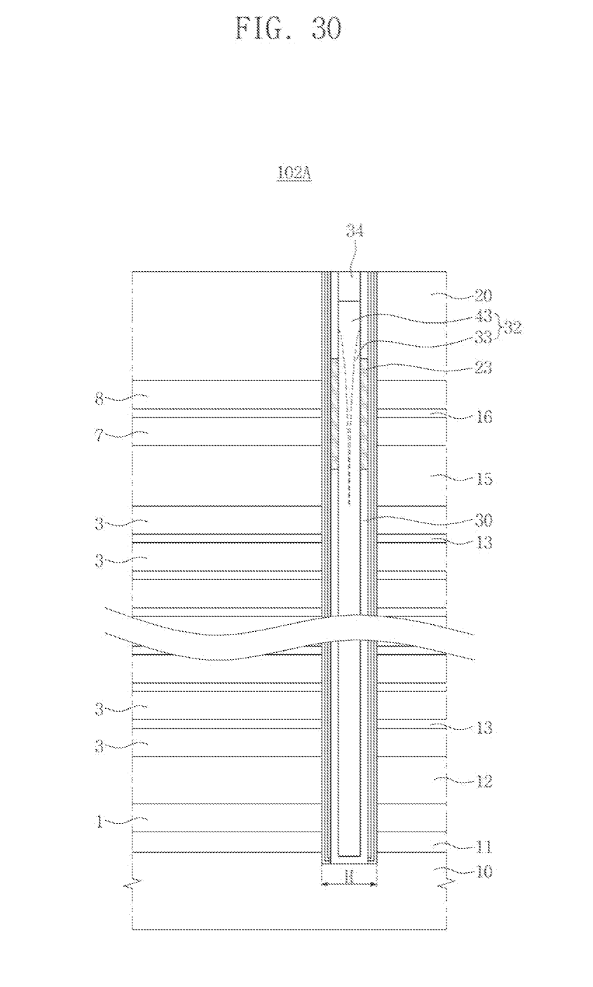

Referring to FIGS. 29 and 30, a method of manufacturing a second exemplary embodiment of a semiconductor device in accordance with principles of inventive concepts may include forming a contact pad 34. The contact pad 34 may be formed by partially removing the channel layer 30 and the contact layer 35 using a planarization process. After the planarization process, the hard mask 31 may be removed, and a top surface of the capping layer 20 may be exposed. Top surfaces of the contact pad 34, the channel layer 30, the dielectric layers DI, and the capping layer 20 may be formed to be at the same level. For example, the planarization process may include a CMP process.

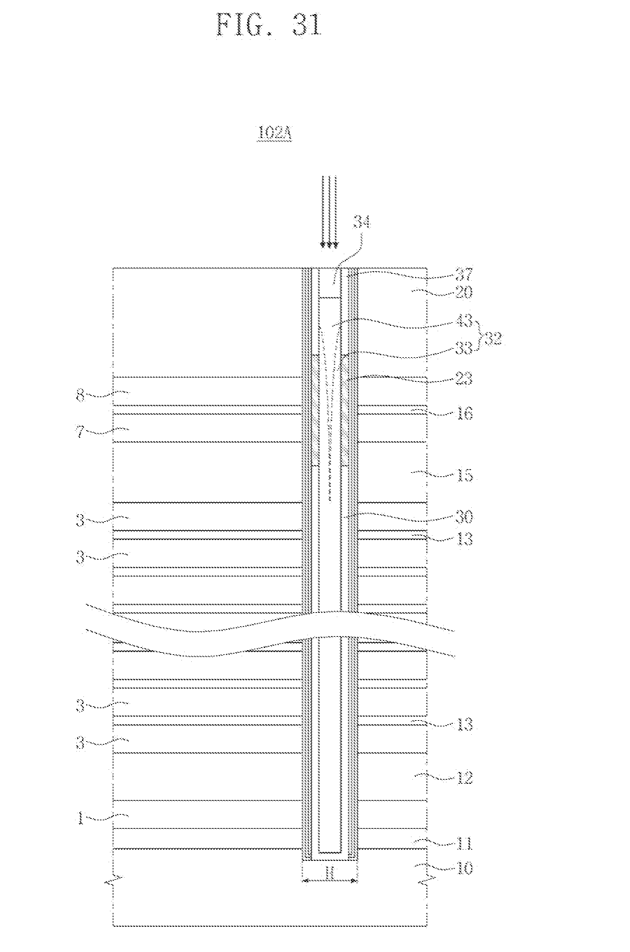

Referring to FIG. 31, a method of manufacturing a second exemplary embodiment of a semiconductor device in accordance with principles of inventive concepts may include performing an ion implantation process on the contact pad 34. N-type impurities may be implanted into the contact pad 34 using the ion implantation process. The depth to which the n-type impurities are implanted into the contact pad 34 may be controlled by an ion implantation energy. The n-type impurities implanted using the ion implantation process may diffuse into the channel layer 30 using subsequent annealing processes. A portion of the channel layer 30 in which the n-type impurities are diffused may be drain region 37. The contact pad 34 may be referred to as an impurity ion implantation region, while the drain region 37 may be referred to as an impurity ion diffusion region. Due to the ion implantation process and the ion diffusion process, an n-type impurity concentration gradient may occur between the contact pad 34 and the drain region 37. The contact pad 34 may have a higher n-type impurity concentration than the drain region 37. For example, the n-type impurities may contain phosphorus (P) or arsenic (As).

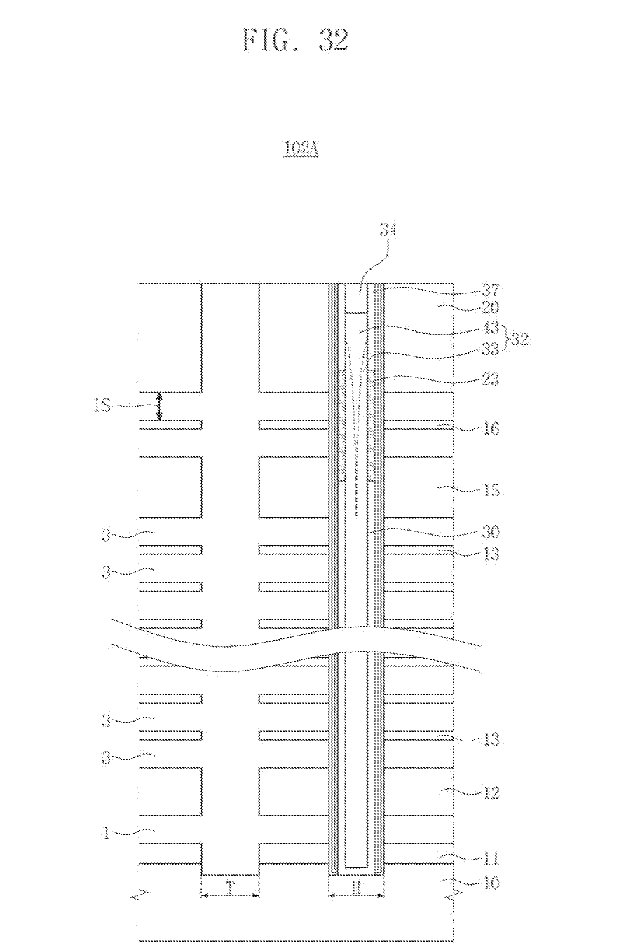

Referring to FIG. 32, a method of manufacturing a second exemplary embodiment of a semiconductor device in accordance with principles of inventive concepts may include forming a trench T and interlayer spaces IS. The formation of the trench T may include alternately anisotropically etching the capping layer 20, the sacrificial layers 1, 3, 7, and 8 and the insulating layers 11, 12, 13, 15, and 16 until a top surface of the substrate 10 is exposed. The interlayer spaces IS may be formed by removing the sacrificial layers 1, 3, 7, and 8 disposed among the insulating layers 11, 12, 13, 15, and 16 through the trench T. An etching process for removing the sacrificial layers 1, 3, 7, and 8 may include an isotropic etching process including a wet etching process or a CDE process. Phosphoric acid (H₃PO₄) may be used as an etchant used in the wet etching process. The etching process may further include a cleaning process using SC-1 (standard cleaning 1).

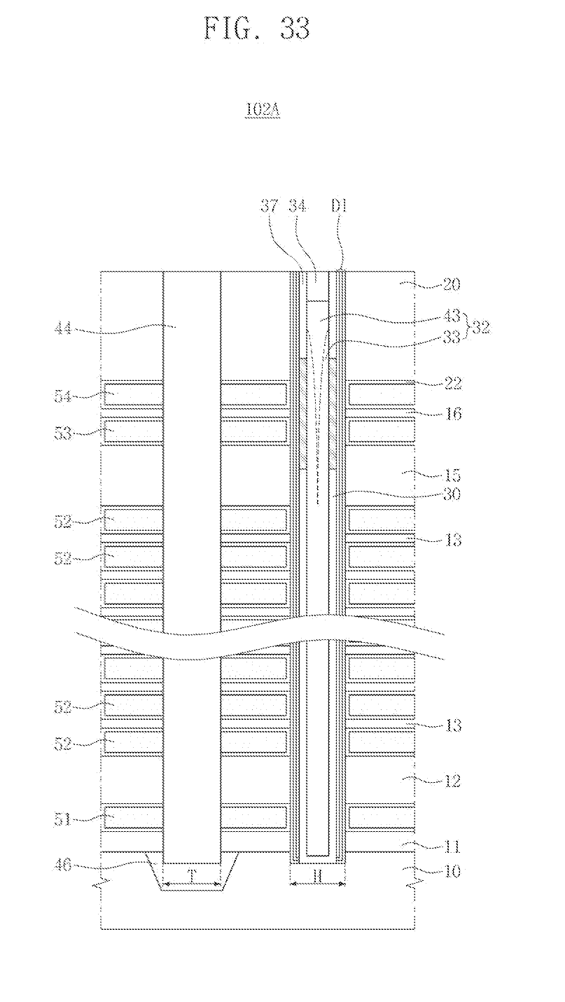

Referring to FIG. 33, a method of manufacturing a second exemplary embodiment of a semiconductor device in accordance with principles of inventive concepts may include forming blocking layers 22, gate electrodes 51, 52, 53, and 54, and a device isolation layer 44.

The blocking layers 22 may be in contact with the exposed surfaces of the barrier layer 24 and the insulating layers 11, 12, 13, 15, and 16. The gate electrodes 51, 52, 53, and 54 may be formed within the interlayer spacers IS. The blocking layer 22 may surround top and bottom surfaces and one side surfaces of the gate electrodes 51, 52, 53, and 54. The device isolation layer 44 may be formed within the trench T.

The blocking layer 22 may include a metal oxide having a larger work function or higher dielectric constant than the barrier layer 24. For example, the metal oxide may include aluminum oxide (Al₂O₃) or hafnium oxide (HfO₂). The gate electrodes 51, 52, 53, and 54 may include a doped silicon, a metal such as tungsten (W), copper (Cu), or aluminum (Al), a conductive metal nitride such as titanium nitride (TiN) or tantalum nitride (TaN), a conductive metal-semiconductor compound such as a metal silicide, or a transition metal such as titanium (Ti) or tantalum (Ta). The device isolation layer 44 may include, for example, silicon oxide (SiOₓ).

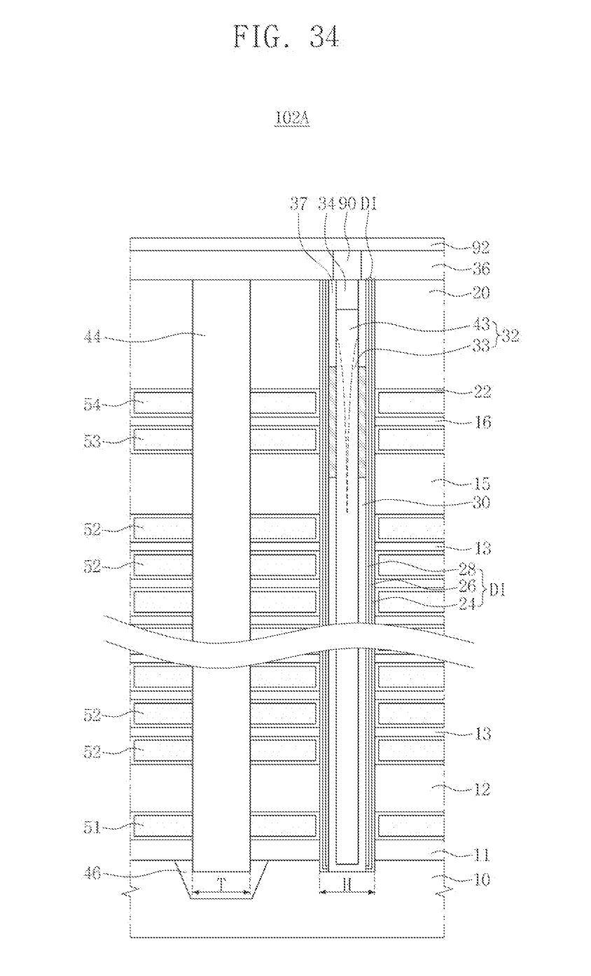

Referring to FIG. 34, a method of manufacturing a second exemplary embodiment of a semiconductor device according to principles of inventive concepts may include forming an interlayer insulating layer 36, a contact plug 90, and a conductive line 92. The interlayer insulating layer 36 may be formed on the top surface of the capping layer 20. A contact plug 90 may be in contact with the top surface of the contact pad 34. A conductive line 92 may be electrically connected to the contact plug 90. The conductive line 92 may be a bit line, and the contact plug 90 may be a bit plug. For example, the contact plug 90 and the conductive line 92 may include a metal, a metal compound, or a metal silicide.

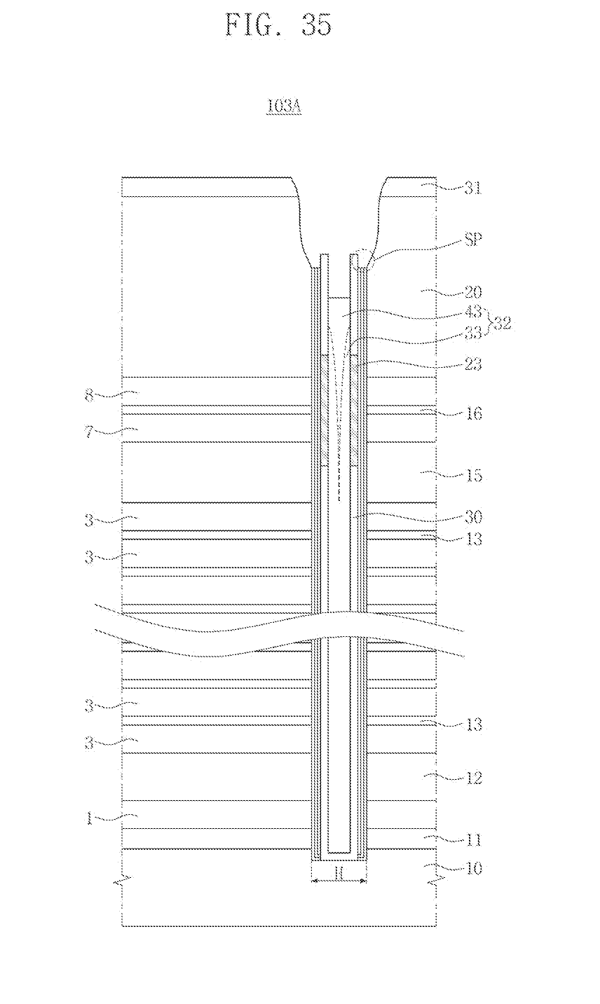

FIGS. 35 through 40 are cross-sectional views illustrating a process of manufacturing a third exemplary embodiment of a semiconductor device in accordance with an exemplary embodiment of inventive concepts.

Processes of stacking insulating layers 11, 12, 13, 15, 16, and 20, forming a contact hole H, forming a channel layer 30 and a gap fill pattern 32 within the contact hole H, and implanting channel impurities may be the same as described above with reference to FIGS. 21 through 25. After forming the channel impurity region 23, the top surface of the upper gap fill pattern 43 may be recessed.

Referring to FIG. 35, a method of manufacturing a third exemplary embodiment of a semiconductor device in accordance with principles of inventive concepts may include recessing the top surface of the upper gap fill pattern 43, removing upper portions of the channel layer 30, and the dielectric layers using an etchback process.

During the etchback process, the thickness of the hard mask 31 may be reduced. A top surface of the dielectric layer DI may be recessed. The channel layer 30 that is in contact with the side surface of the capping layer 20 may be etched during the removal of the upper gap fill pattern 43. A top surface of the upper gap fill pattern 43 may be formed at a lower level than the top surfaces of the dielectric layers DI. The top surface of the channel layer 30 may be formed at a higher level than the top surfaces of the dielectric layers DI. A side surface of the channel layer 30 which does not in contact with the dielectric layer may be exposed. The small space SP may be formed between the exposed side surface of the channel layer 30 and a side surface of the capping layer 20.

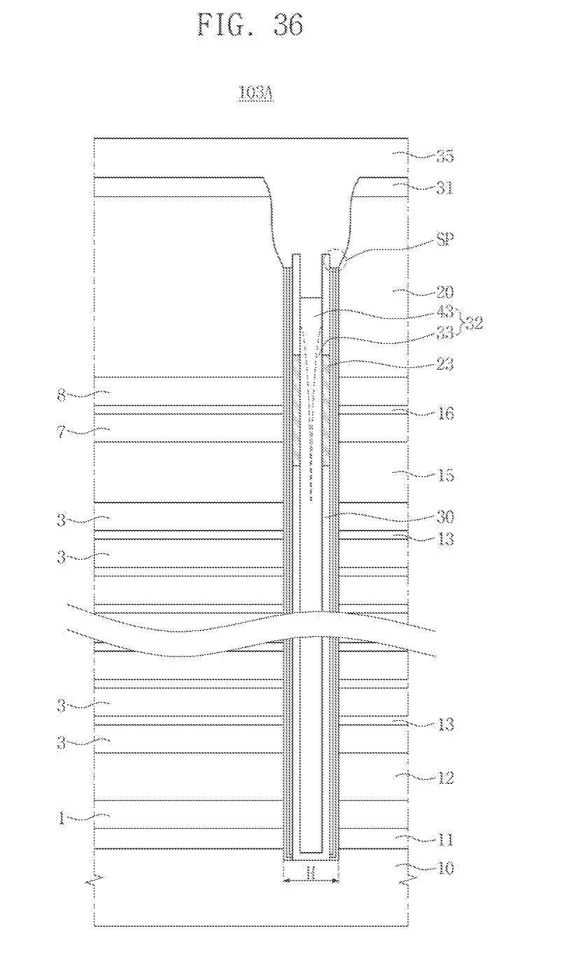

Referring to FIG. 36, a method of manufacturing a third exemplary embodiment of a semiconductor device in accordance with principles of inventive concepts may include forming contact layer 35. The contact layer 35 may be formed along a top surface of the gap fill pattern 32, side and top surfaces of the channel layer 30, a top surface of the hard mask 31, a top surface of the dielectric layer GD, and a side surface of the capping layer 20. The small space SP may be filled with the contact layer 35. For example, the contact layer 35 may include C-doped poly-Si.

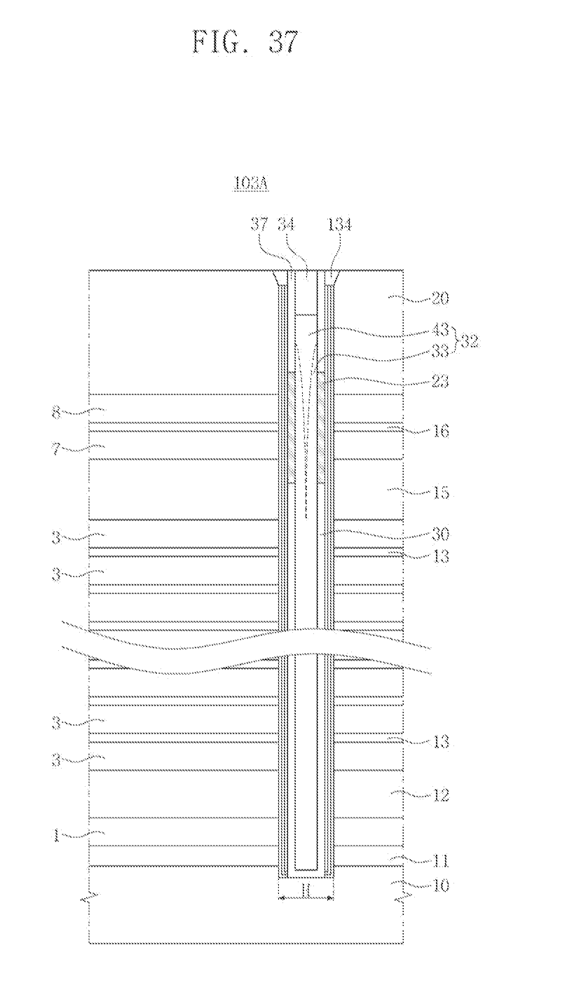

Referring to FIGS. 36 and 37, a method of manufacturing a third exemplary embodiment of a semiconductor device in accordance with principles of inventive concepts may include forming a contact pad 34 and a contact ring 134. A contact pad 34 and a contact ring 134 may be formed by the planarization process. The contact pad 34 and contact ring 134 may be formed by removing a portion of the contact layer 35 through the planarization process. The small space SP may be filled with the contact ring 134. The contact ring 134 may have a ring shape on the outer side surface of the channel layer 30. A top surface of the contact pad 34, the channel layer 30, and the contact ring 134 may be formed to be at a same level. For example, the planarization process may include a CMP process.

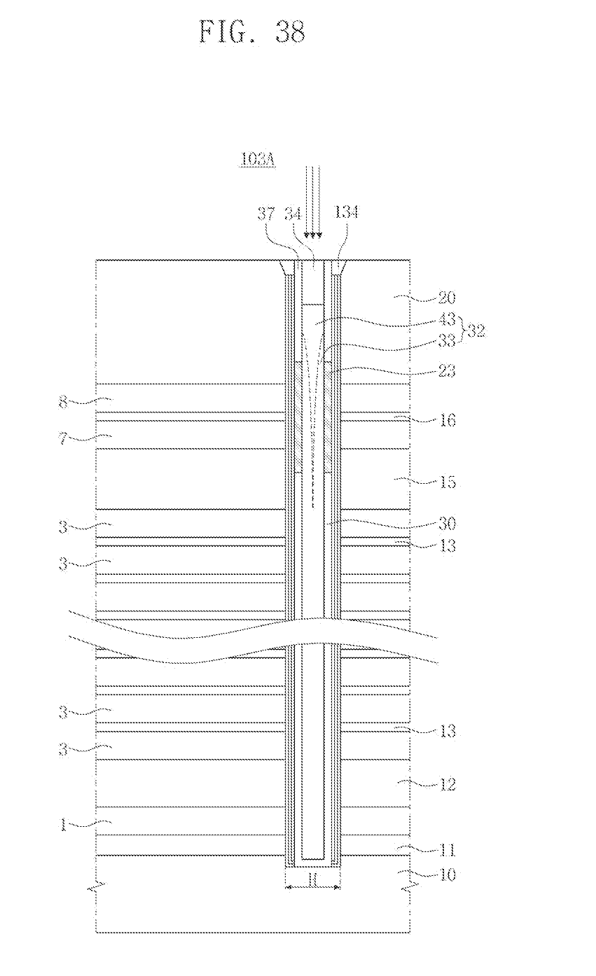

Referring to FIG. 38, a method of manufacturing a third exemplary embodiment of a semiconductor device in accordance with principles of inventive concepts may include performing an ion implantation process on the contact pad 34.

Due to the ion implantation process, n-type impurities may be implanted into the contact pad 34. A depth to which the n-type impurities are implanted may be controlled by an energy amount of the ion implantation process. The n-type impurities implanted using the ion implantation process may diffuse into the channel layer 30 using a subsequent annealing process. A portion of the channel layer 30 in which the n-type impurities are diffused may be referred to as drain region 37. The contact pad 34 may be referred to as an impurity ion implantation region, while the drain region 37 and the contact ring 134 may be referred to as an impurity ion diffusion region. The contact pad 34 may have a higher n-type impurity concentration than the drain region 37. For example, the n-type impurities may contain arsenic (As) or phosphorus (P).

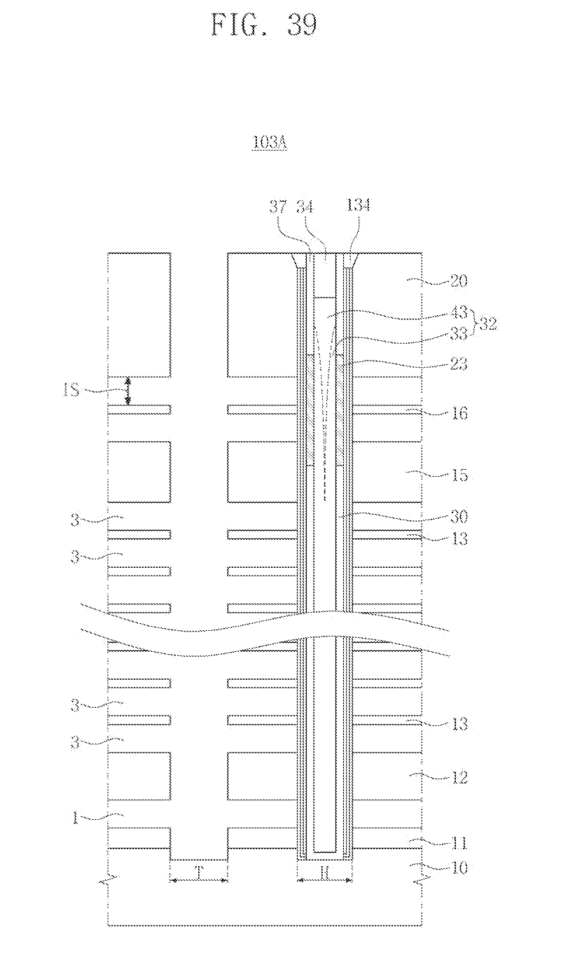

Referring to FIGS. 38 and 39, a method of manufacturing a third exemplary embodiment of a semiconductor device in accordance with principles of inventive concepts may include forming a trench T and interlayer spaces IS.

The formation of the trench T may include alternately anisotropically etching the capping layer 20, the sacrificial layers 1, 3, 7, and 8, and the insulating layers 11, 12, 13, 15, and 16 until the top surface of the substrate 10 is exposed. The interlayer spaces IS may be formed by removing the sacrificial layers 1, 3, 7, and 8 disposed among the insulating layers 11, 12, 13, 15, and 16 through the trench T. The process of etching the sacrificial layers 1, 3, 7, and 8 may be a wet etching process. The wet etching process may be an isotropic etching process using phosphoric acid (H₃PO₄) with respect to the sacrificial layers 1, 3, 7, and 8 including silicon nitride (SiNₓ).

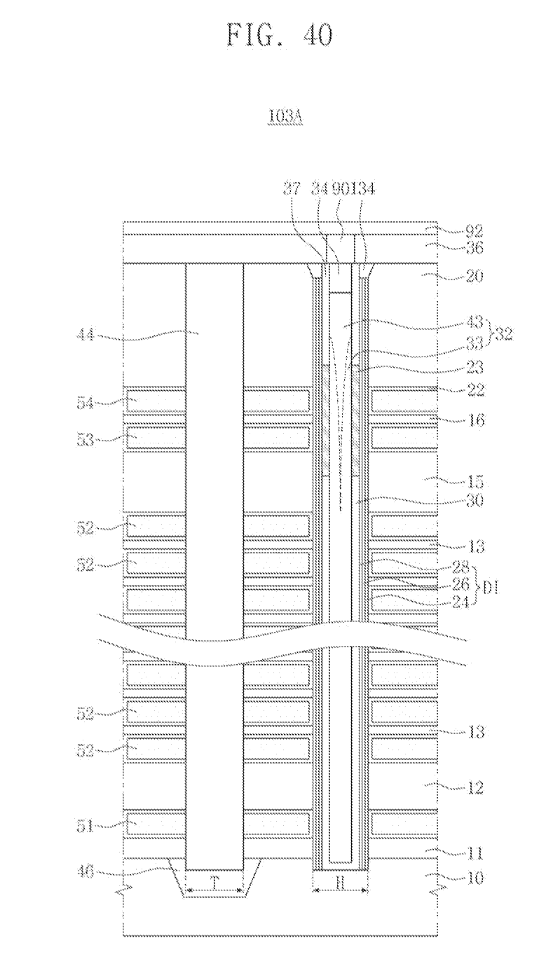

Referring to FIGS. 39 and 40, a method of manufacturing a third exemplary embodiment of a semiconductor device in accordance with principles of inventive concepts may include forming blocking layers 22, gate electrodes 51, 52, 53, and 54, a device isolation layer 44, a interlayer insulating layer 36, a contact plug 90, and a conductive line 92. The blocking layers 22 may be in contact with the exposed surfaces of the barrier layer 24 and the insulating layers 11, 12, 13, 15, and 16. The gate electrodes 51, 52, 53, and 54 may be formed in the interlayer spacers IS. The blocking layers 22 may surround top and bottom surfaces and one side surfaces of the gate electrodes 51, 52, 53, and 54. The device isolation layer 44 may be formed within the trench T. The blocking layers 22 may include a metal compound having a higher dielectric constant or larger work function than the barrier layer 24. For example, the metal compound may include aluminum oxide (Al₂O₃) or hafnium oxide (HfO₂). The interlayer insulating layer 36 may be formed on a top surface of the capping layer 20. The contact plug 90 may be formed to electrically contact a top surface of the contact pad 34 by passing through the interlayer insulating layer 36. The conductive line 92 may be formed to electrically contact the contact plug 90.

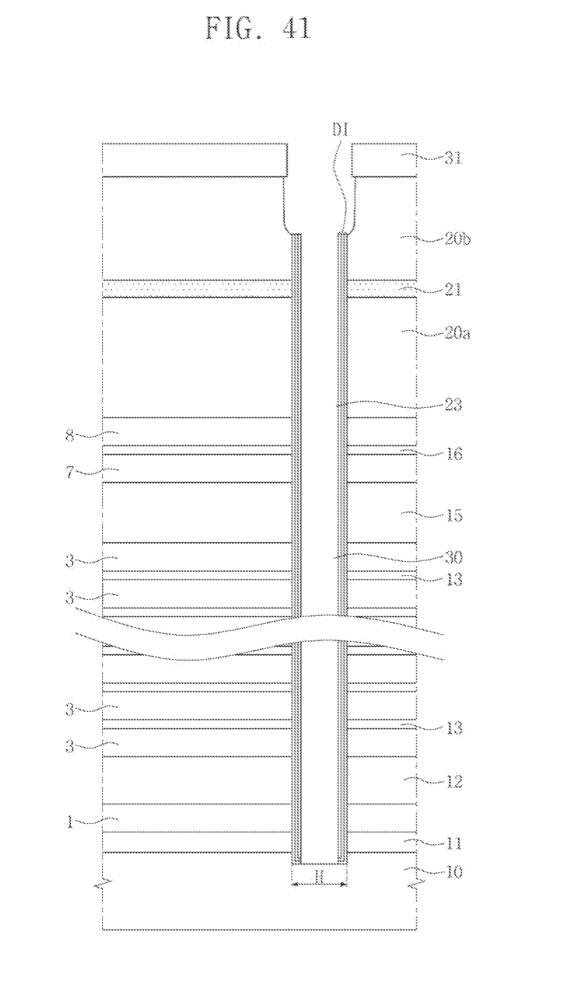

FIGS. 41 through 44 are cross-sectional views illustrating processes of a method of manufacturing a semiconductor device in accordance with an exemplary embodiment of inventive concepts.

Since components to be mentioned in the following processes, for example, dielectric layers, sacrificial layers, and insulating layers, are described above, detailed descriptions thereof will be omitted below.

Referring to FIG. 41, the method of manufacturing the semiconductor device in accordance with the exemplary embodiment of the inventive concepts may include forming insulating layers 11, 12, 13, 15, 16, and 20, sacrificial layers 1, 3, 7, and 8, a lower capping layer 20a, an etch stop layer 21, and an upper capping layer 20b on a substrate.

The method of manufacturing the semiconductor device in accordance with the exemplary embodiment of the inventive concepts may include forming a channel hole H through a hard mask 31, the insulating layers 11, 12, 13, 15, 16, and 20, the sacrificial layers 1, 3, 7, and 8, the lower capping layer 20a, the etch stop layer 21, and the upper capping layer 20b and forming dielectric layers DI on an inner wall of the channel hole H.

A side surface of the upper capping layer 20b may be exposed between top surfaces of the dielectric layers DI and the hard mask 31. The etch stop layer 21 may be formed between the lower capping layer 20a and the upper capping layer 20b. The top surfaces of the dielectric layers DI may be formed at a lower level than a top surface of the upper capping layer 20b.

The hard mask 31 may include poly-Si. The sacrificial layers 1, 3, 7, and 8 may be formed of a material having an etch selectivity with respect to the insulating layers 11, 12, 13, 15, and 16. For example, the insulating layers 11, 12, 13, 15, and 16 may be formed of silicon oxide (SiOₓ), and the sacrificial layers 1, 3, 7, and 8 may be formed of silicon nitride (SiNₓ). The upper and lower capping layers 20a and 20b may be formed of silicon oxide (SiOₓ). The etch stop layer 21 may be formed of silicon nitride (SiNₓ).

Referring to FIG. 42, the method of manufacturing the semiconductor device in accordance with the exemplary embodiment of the inventive concepts may include forming channel layer 30 and forming a gap fill pattern 32 within the channel hole H. The method of manufacturing the semiconductor device in accordance with the exemplary embodiment of the inventive concepts may include forming a channel impurity region 23 in the channel layer 30 corresponding to side surfaces of first and second upper sacrificial layers 7 and 8.

The channel layer 30 may be in contact with the side surface of the upper capping layer 20b and a tunneling layer (28) disposed in an outermost dielectric layer DI, from among the dielectric layers DI. The gap fill pattern 32 may be in contact with the channel layer 30 and fill the channel hole H. A top surface of the gap fill pattern 32 may be at the same level with a top surface of the hard mask 31.

The formation of the channel impurity region 23 may include implanting impurities into the channel layer 30 corresponding to side surfaces of the first upper sacrificial layer 7, a fifth insulating layer 16, and the second upper sacrificial layer 8. The impurities may include boron (B).

An ion projection range Rp, which denotes an average penetration depth of the boron (B), may be controlled by a thickness of the etch stop layer 21 and a thickness of the hard mask 31. Specifically, heights of the gap fill pattern 32 and the channel layer 30, which are media through which the impurities penetrate, may be controlled by varying the thickness of the etch stop layer 21 and the thickness of the hard mask 31. That is, the heights of the gap fill pattern 32 and the channel layer 30 may be controlled to obtain a desired ion projection range Rp.

The gap fill pattern 32 may include silicon oxide (SiOx).

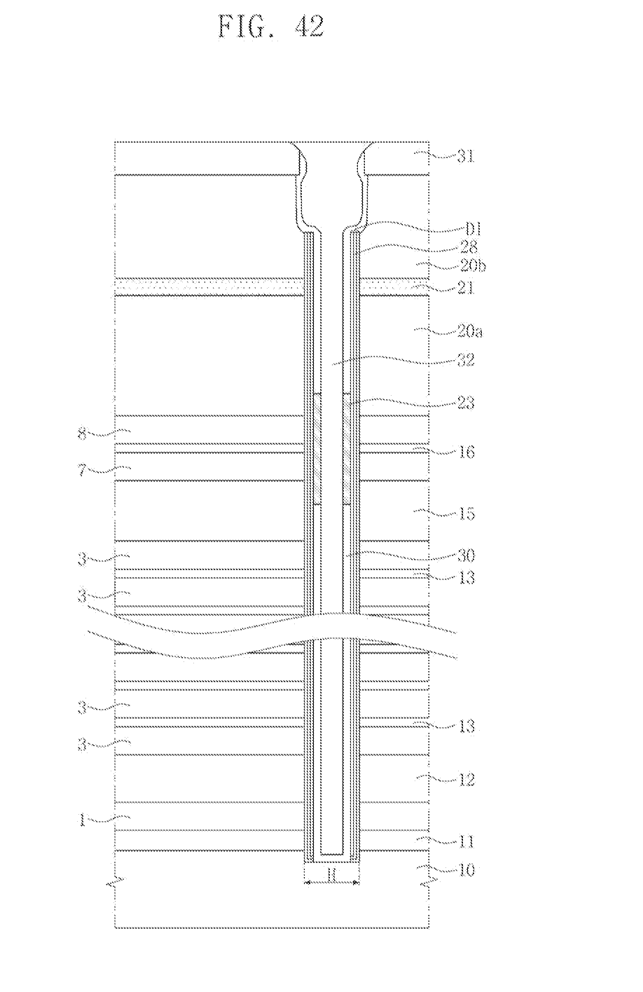

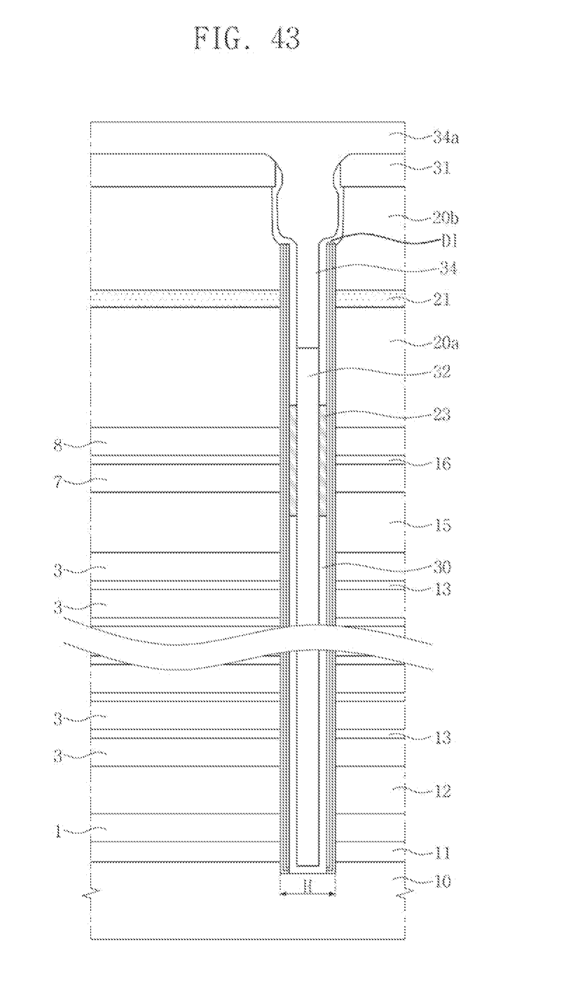

Referring to FIG. 43, the method of manufacturing the semiconductor device in accordance with the exemplary embodiment of the inventive concepts may include recessing the gap fill pattern 34 and forming a contact layer 34a on a top surface of the recessed gap fill pattern 34.

The top surface of the recessed gap fill pattern 34 may be located between a bottom surface of the etch stop layer 21 and a top surface of the second upper sacrificial layer 8. The contact layer 34a may be located on the top surface of the gap fill pattern 32, and fill the channel hole H corresponding to an upper portion of the gap fill pattern 32.

The contact layer 34a may be formed of poly-Si doped with carbon (C).

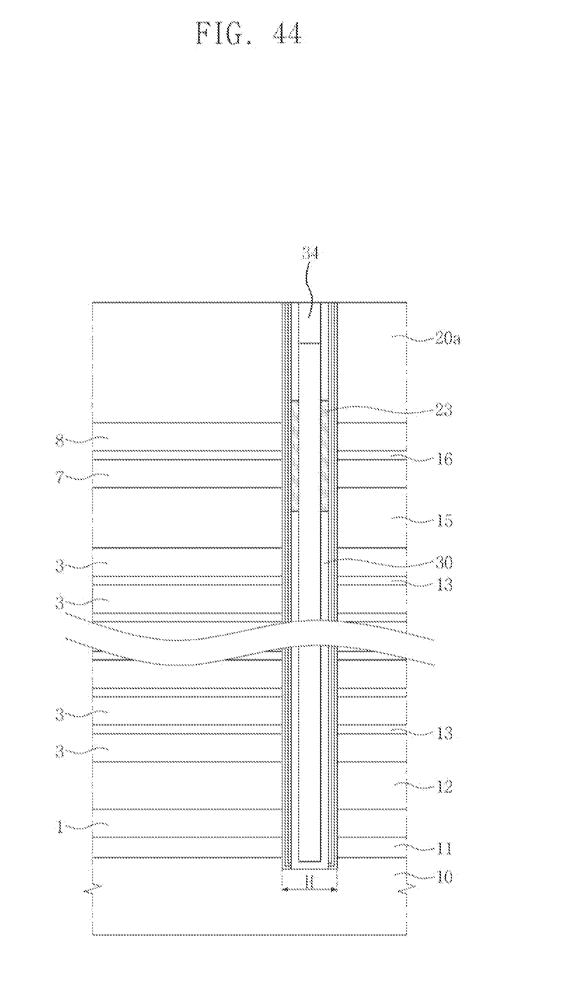

Referring to FIGS. 43 and 44, the method of manufacturing the semiconductor device in accordance with the exemplary embodiment of the inventive concepts may include forming a contact pad 34 on the top surface of the gap fill pattern 32.

The formation of the contact pad 34 may include a dry etching process and a CMP process.

By selectively using the above-described etching processes, a portion of the contact layer 30, the hard mask 31, portions of the dielectric layers DI, a portion of the channel layer 30, the upper capping layer 20b, and the etch stop layer 21 may be removed.

The etch stop layer 21 may be used as a CMP stopper. After the above-described etching processes, a cleaning process may be performed using a wet etching process.

A top surface of the contact pad 34 may be at the same level with a surface of the lower capping layer 20a from which the etch stop layer 21 is removed.

Subsequent processes may be the same as the processes described in the previous embodiment with reference to FIGS. 16 through 20 or the processes described in the previous embodiment with reference to FIGS. 38 through 40.

As mentioned in the previous embodiments, for example, in the embodiments shown in FIGS. 24 and 34, the gap fill pattern 32 may include a lower gap fill pattern 33 and an upper gap fill pattern 43.

In the above-described processes, the hard mask 31 may be formed of silicon nitride (SiNₓ).

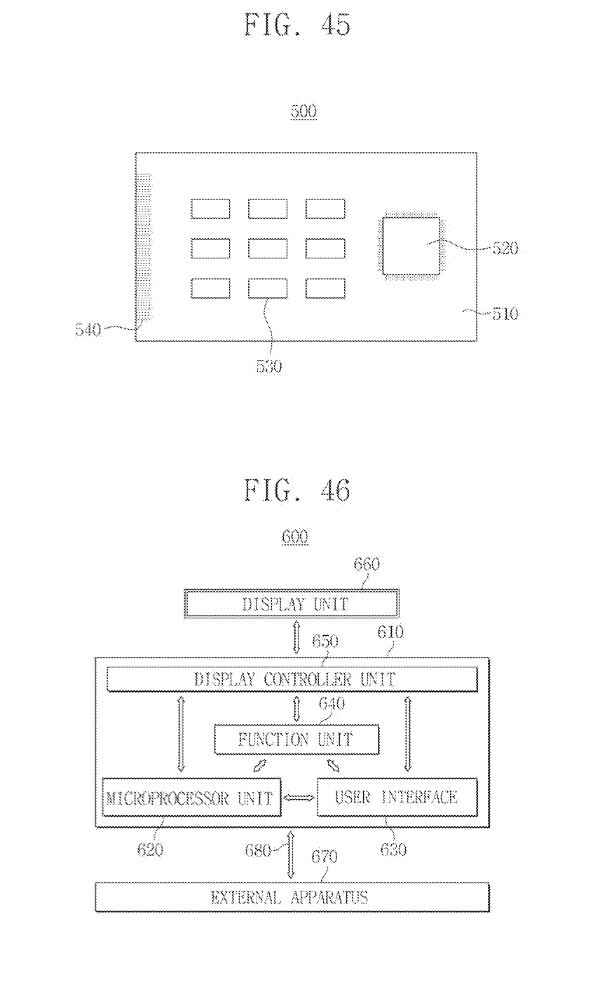

FIG. 45 is a conceptual diagram of a semiconductor module 500 including at least one semiconductor device in accordance with principles of inventive concepts, such as one of the semiconductor devices 101, 102, and 103. Referring to FIG. 41, the semiconductor module 500 in accordance with principles of inventive concepts may include one of the semiconductor devices 101, 102, and 103, which may be mounted on a semiconductor module substrate 510. The semiconductor module 500 may further include a microprocessor (MP) 520 mounted on the module substrate 510. Input/output (I/O) terminals 540 may be disposed on at least one side of the module substrate 510. The semiconductor module 500 may include a memory card or a solid-state drive (SSD).

FIG. 46 is a conceptual block diagram of an electronic system including a semiconductor device in accordance with principles of inventive concepts, such as one of the semiconductor devices 101, 102, and 103. Referring to FIG. 42, semiconductor devices 101, 102, and 103 may be applied to an electronic system 600. The electronic system 600 may include a body 610, a microprocessor (MP) unit 620, a power supply 630, a function unit 640, and a display controller unit 650. The body 610 may be a system board or mother board having a PCB. The MP unit 620, the power supply 630, the function unit 640, and the display controller unit 650 may be mounted on the body 610. A display unit 660 may be disposed on a top surface of the body 610 or outside the body 610. For example, the display unit 660 may be disposed on a surface of the body 610 and display an image processed by the display controller unit 650. The power supply 630 may receive a predetermined voltage from an external battery (not shown), divide the predetermined voltage into various voltage levels, and transmit divided voltages to the MP unit 620, the function unit 640, and the display controller unit 650. The MP unit 620 may receive a voltage from the power supply 630 and control the function unit 640 and the display unit 660. The function unit 640 may implement various functions of the electronic system 600. For instance, when the electronic system 600 is a mobile electronic device such as a portable phone, the function unit 640 may include several elements capable of wireless communication functions, such as output of an image to the display unit 660 or output of a voice to a speaker, by dialing or communication with an external apparatus 670. When the function unit 640 includes a camera, the function unit 640 may serve as an image processor. In exemplary embodiments, when the electronic system 600 is connected to a memory card to increase capacity, the function unit 640 may be a memory card controller. The function unit 640 may exchange signals with the external apparatus 670 through a wired or wireless communication unit 680. In addition, when the electronic system 600 needs a universal serial bus (USB) to expand functions thereof, the function unit 640 may serve as an interface controller. The semiconductor devices 101, 102, and 103 described in the embodiments of inventive concepts may be included in the function unit 640.

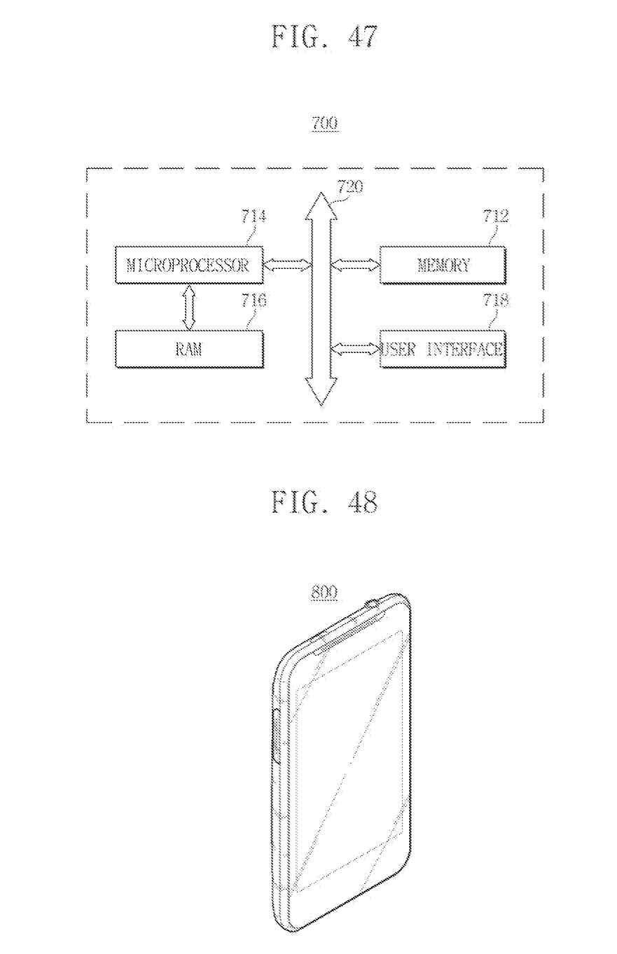

FIG. 47 is a schematic block diagram of an electronic system 700 in accordance with principles of inventive concepts. Referring to FIG. 35, the electronic system 700 may include a semiconductor device in accordance with principles of inventive concepts, such as one of the semiconductor devices 101, 102, and 103. The electronic system 700 may be applied to a mobile electronic device or a computer. For example, the electronic system 700 may include a memory system 712, an MP 714, a random access memory (RAM) 716, and a user interface 718, which may communicate data using a bus 720. The MP 714 may program and control the electronic system 700. The RAM 716 may be used as an operation memory of the MP 714. For example, the MP 714 or the RAM 716 may include at least one of the semiconductor devices 101, 102, and 103 according to the embodiments of inventive concepts. The MP 714, the RAM 716, and/or other elements may be assembled within a single package. The user interface 718 may be used to input data to the electronic system 700 or output data from the electronic system 700. The memory system 712 may store codes for operating the MP 714, data processed by the MP 714, or external input data. The memory system 712 may include a controller and a memory.

FIG. 48 is a schematic diagram of a mobile electronic device 800 in accordance with principles of inventive concepts. The mobile electronic device 800 may be implemented as a tablet personal computer (PC), for example. A semiconductor device in accordance with principles of inventive concept, such as one of the semiconductor devices 101, 102, and 103 may be used not only for a tablet PC but also for a portable computer such as a laptop computer, an MPEG-1 audio layer 3 (MP3) player, an MP4 player, a navigation device, a solid-state disk (SSD), a desktop computer, or electronic devices for automotive and household uses.

A 3-dimensional vertical-cell-type semiconductor device in accordance with principles of inventive concepts may employ an implantation process that results in a distribution of implanted ions that reduces variations in threshold voltages among transistors. By doing so, a semiconductor device in accordance with principles of inventive concepts may operate within a preferred range of threshold voltages, thereby ensuring reliable operation while, at the same time, minimizing power consumption. In accordance with principles of inventive concepts, the ion implantation process may be performed after a poly-stop CMP process, thereby simplifying a process of manufacturing a vertical-cell-type semiconductor device.

The foregoing is illustrative of embodiments and is not to be construed as limiting thereof. Although exemplary embodiments have been described, those skilled in the art will readily appreciate that many modifications are possible without materially departing from the spirit and scope of inventive concepts. Accordingly, all such modifications are intended to be included within the scope of inventive concepts as defined in the claims. In the claims, means-plus-function clauses are intended to cover the structures described herein as performing the recited function, and not only structural equivalents but also equivalent structures.

What is claimed is:

1. A semiconductor device comprising:
insulating layers and gate electrodes alternately stacked on a substrate;
wherein the gate electrodes include a ground selection gate electrode, cell gate electrodes, and string selection gate electrodes;
a channel hole disposed through the insulating layer and the gate electrodes;
a gap fill pattern, a channel layer, and dielectric layers disposed within the channel hole;
a channel impurity region formed in the channel layer corresponding to the string selection gate electrodes and containing a first conductivity type impurities; and
a contact pad disposed on the gap fill pattern,
wherein the contact pad includes a second conductivity type impurities and is free from the first conductivity type impurities.

2. The device of claim 1, wherein the contact pad contains carbon (C) and silicon (Si).

3. The device of claim 1, wherein the first conductivity type impurity concentration of the channel impurity region is higher than that of the channel layer.

4. The device of claim 1, wherein the string selection gate electrodes include first and second string selection gate electrodes, and a highest impurity concentration point of the channel impurity region is positioned between the first and second string selection gate electrodes.

5. The device of claim 4, wherein the second string selection gate electrode is disposed over the first string selection gate electrode,
a top end of the channel impurity region is disposed at a higher level than the second string selection gate electrode, and
a bottom end of the channel impurity region is disposed at a lower level than the first string selection gate electrode.

6. The device of claim 1, wherein the dielectric layers include a barrier layer is in contact with an inner wall of the channel, a charge trap layer is in contact with the barrier layer, and a tunneling layer is in contact with the charge trap layer.

7. The device of claim 1, wherein a top surface of the gap fill pattern is at a higher level than the channel impurity region.

8. The device of claim 6, wherein the gap fill pattern comprises a lower gap fill pattern and an upper gap fill pattern disposed on the lower gap fill pattern,
a center of the top surface of the lower gap fill pattern is a lower level than both ends of the top surface of the lower gap fill pattern.

9. The device of claim 8, wherein the both ends of top surface of the lower gap fill pattern is at a higher level than a top end of the channel impurity region, and
the center of the top surface of the lower gap fill pattern is at a lower level than a bottom end of the channel impurity region.

10. The device of claim 9, further comprising the channel impurity region disposed between the lower gap fill pattern and the dielectric layers.

11. The device of claim 1, further comprising a drain region disposed on the channel impurity region in the channel layer.

12. The device of claim 11, wherein the drain region is in contact with a side surface of the contact pad.

13. The device of claim 11, wherein the drain region contains n-type impurities and has an n-type impurity concentration lower than the contact pad.

14. The device of claim 1, wherein the first conductivity type impurities is p-type impurities, and the p-type impurities include boron (B).

15. A semiconductor device comprising:
insulating layers and gate electrodes alternately stacked on a substrate;
wherein the gate electrodes include a ground selection gate electrode, cell gate electrodes, and string selection gate electrodes;
a channel hole disposed through the insulating layer and the gate electrodes;
dielectric layers, channel layer, and a gap fill pattern disposed within the channel hole;
wherein the channel layer is disposed between the gap fill pattern and the dielectric layers, top surfaces of the dielectric layers are at a lower level than a top surface of the channel layer, and a top surface of the gap fill pattern is at a lower level than the top surfaces of the dielectric layers,
a contact pad disposed on the gap fill pattern and a contact ring disposed on the dielectric layers; and
wherein top surfaces of the gap fill pattern, the channel layer, the contact ring, a uppermost insulating layer are at a same level,
a drain region disposed on the channel impurity region.

16. A vertical-cell-type semiconductor device, comprising:
first and second vertically stacked transistor electrodes; and
a channel impurity region vertically spanning the first and second transistor electrodes, with a point of highest impurity concentration at a level between the first and second transistor electrodes.

17. The semiconductor device of claim 16, wherein the channel impurity region has a Gaussian distribution of impurity ions symmetrically distributed about the point of highest impurity concentration.

18. The semiconductor device of claim 17, further including structure to broaden the Gaussian distribution of impurity ions.

19. The semiconductor device of claim 18, wherein the structure includes material to lengthen the implantation path of impurity ions to thereby broaden the Gaussian distribution.
